(19) United States
(12) Patent Application Publication
(10) Pub. No.: US 2024/0395682 A1
(43) Pub. Date: Nov. 28, 2024

(54) PRINTED CIRCUIT BOARD AND METHOD OF MANUFACTURING THE SAME

(71) Applicant: SAMSUNG ELECTRO-MECHANICS CO., LTD., Suwon-si (KR)

(72) Inventors: Hyun Hu Lee, Suwon-si (KR); Sang Ho Jeong, Suwon-si (KR); Chang Hwa Park, Suwon-si (KR); Deok Hong Jo, Suwon-si (KR); Sang Won Han, Suwon-si (KR); Jong Eun Park, Suwon-si (KR)

(73) Assignee: SAMSUNG ELECTRO-MECHANICS CO., LTD., Suwon-si (KR)

(21) Appl. No.: 18/666,215

(22) Filed: May 16, 2024

(30) Foreign Application Priority Data
May 23, 2023 (KR) 10-2023-0066307
Nov. 15, 2023 (KR) 10-2023-0158480

(51) Int. Cl. H01L 23/498; H01L 21/48; H01L 23/00

(52) U.S. Cl. CPC H01L 23/49822; H01L 21/4857; H01L 23/49838; H01L 24/13; H01L 24/16; H01L 23/49894; H01L 2224/13111; H01L 2224/13124; H01L 2224/13139; H01L 2224/13147; H01L 2224/16238

(57) ABSTRACT

A printed circuit board and a method of manufacturing the same are provided. The printed circuit board includes a first insulating layer, a first metal layer having a first portion protruding upwardly of the first insulating layer and a second portion embedded in the first insulating layer, and a barrier layer disposed at a boundary between the first insulating layer and the second portion and extending to a lower surface of the first insulating layer. The first portion and the second portion are integrated.

### CROSS-REFERENCE TO RELATED APPLICATION(S)

This application claims benefit of priority to Korean Patent Application No. 10-2023-0158480 filed on Nov. 15, 2023 and Korean Patent Application No. 10-2023-0066307 filed on May 23, 2023 in the Korean Intellectual Property Office, the disclosures of which are incorporated herein by reference in their entirety.

### TECHNICAL FIELD

The present disclosure relates to a printed circuit board and a method of manufacturing the printed circuit board.

To respond to the recent trend for lightweighting and miniaturization of mobile devices, the need to implement lightweight, compact printed circuit boards mounted therein has been increasing. In addition, as demand for high-performance server printed circuit boards increases, demand for high-density circuits connecting logic semiconductors and memory semiconductors, or logic semiconductors and logic semiconductors, is also rapidly increasing. Research is continuing to improve the reliability of connection with electronic components such as semiconductor chips with high-density microcircuits and the reliability of connection with the main board.

### SUMMARY

An aspect of the present disclosure is to provide a printed circuit board, in which connection with electronic components having high-density microcircuits and/or connection with a main board may be performed, and a method of manufacturing the printed circuit board.

An aspect of the present disclosure is to provide a printed circuit board in which a microcircuit-implemented structure protrudes to an outermost surface, and a method of manufacturing the printed circuit board.

An aspect of the present disclosure is to provide a printed circuit board having improved reliability and a method of manufacturing the printed circuit board.

According to an aspect of the present disclosure, a printed circuit board includes a first insulating layer, a first metal layer having a first portion protruding upwardly of the first insulating layer and a second portion embedded in the first insulating layer, and a barrier layer disposed at a boundary between the first insulating layer and the second portion and extending to a lower surface of the first insulating layer. The first portion and the second portion are integrated.

According to an aspect of the present disclosure, a method of manufacturing a printed circuit board includes forming a temporary layer on a carrier substrate, forming a first insulating layer on the temporary layer, forming a first through-hole penetrating through the first insulating layer, forming a recess by removing at least a portion of the temporary layer, forming a barrier layer along an inner wall of the first through-hole, an inner wall of the recess, and a lower surface of the first insulating layer, forming a first metal layer in the first through-hole and the recess, and removing the carrier substrate and the temporary layer.

According to an aspect of the present disclosure, a circuit board includes a first insulating layer, a second insulating layer on which the first insulating layer is disposed, a first metal layer extending from the second insulating layer and disposed partially in the first insulating layer, a barrier layer disposed between the first insulating layer and the second insulating layer and extending to over at least a portion of the first metal layer, a first wiring layer disposed on the second insulating layer, and a first via layer penetrating through at least a portion of the second insulating layer to connect the first wiring layer and the first metal layer. The barrier layer is spaced apart from the first via layer.

According to an aspect of the present disclosure, a circuit board includes a first insulating layer, a second insulating layer on which the first insulating layer is disposed, a first metal layer extending from the second insulating layer and disposed partially in the first insulating layer, a first via layer penetrating through at least a portion of the second insulating layer to be in contact with the first metal layer. The first metal layer has two portions, side surfaces of which have a step therebetween.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIGS. 3A and 3B are cross-sectional views schematically illustrating a printed circuit board according to a first embodiment;

FIGS. 4A and 4B are cross-sectional views schematically illustrating a printed circuit board according to a second embodiment;

FIGS. 5A and 5B are cross-sectional views schematically illustrating a printed circuit board according to a third embodiment;

FIG. 6 is a cross-sectional view schematically illustrating a printed circuit board according to a fourth embodiment;

FIG. 7 is a cross-sectional view schematically illustrating a printed circuit board according to a fifth embodiment;

FIG. 8 is a cross-sectional view schematically illustrating a printed circuit board according to a sixth embodiment;

FIGS. 9A and 9B are cross-sectional views schematically illustrating a printed circuit board according to a seventh embodiment;

FIGS. 10A and 10B are cross-sectional views schematically illustrating a printed circuit board according to an eighth embodiment;

FIGS. 11A and 11B are cross-sectional views schematically illustrating a printed circuit board according to a ninth embodiment;

FIGS. 12A to 12E are cross-sectional views schematically illustrating various shapes of a first metal layer of a printed circuit board;

FIGS. 13A to 13M are cross-sectional views schematically illustrating a method of manufacturing a printed circuit board according to the first embodiment;

FIG. 14 is a cross-sectional view schematically illustrating an operation of the method of manufacturing a printed circuit board according to the second embodiment;

FIG. 15 is a cross-sectional view schematically illustrating an operation of the method of manufacturing a printed circuit board according to the third embodiment;

FIG. 16 is a cross-sectional view schematically illustrating an operation of the method of manufacturing a printed circuit board according to the fourth embodiment;

FIG. 17 is a cross-sectional view schematically illustrating an operation of the method of manufacturing a printed circuit board according to the fifth embodiment;

FIG. 18 is a cross-sectional view schematically illustrating an operation of the method of manufacturing a printed circuit board according to the sixth embodiment;

FIG. 19 is a cross-sectional view schematically illustrating an operation of the method of manufacturing a printed circuit board according to the seventh embodiment;

FIG. 20 is a cross-sectional view schematically illustrating an operation of the method of manufacturing a printed circuit board according to the eighth embodiment; and

FIG. 21 is a cross-sectional view schematically illustrating an operation of the method of manufacturing a printed circuit board according to the ninth embodiment.

### DETAILED DESCRIPTION

Hereinafter, the present disclosure will be described with reference to the accompanying drawings. The shapes and sizes of elements in the drawings may be exaggerated or reduced for clearer descriptions.

### Electronic Device

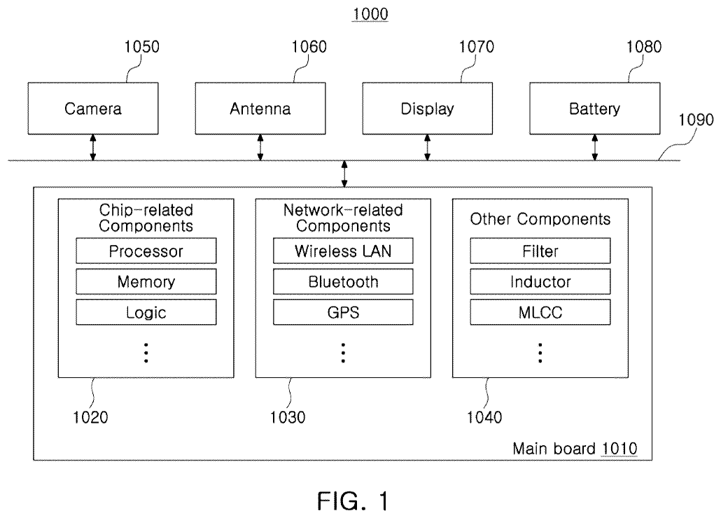

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related electronic components. In addition, the chip related components 1020 may also be combined with each other. The chip related components 1020 may be in the form of a package including the above-described chips or electronic components.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, or the like. In addition, other components 1040 may also be combined with each other, with the chip related components 1020 or the network related components 1030 described above.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like. However, these other electronic components are not limited thereto, and may also be an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, other electronic components for various uses may also be included depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

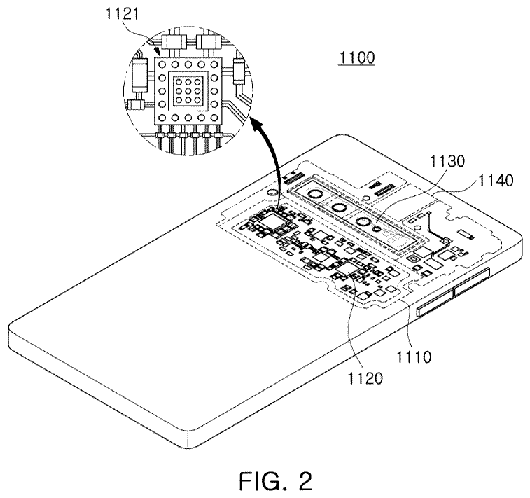

FIG. 2 is a schematic perspective view illustrating an example of an electronic device.

Referring to FIG. 2, the electronic device may be, for example, a smartphone 1100. A motherboard 1110 is accommodated inside the smartphone 1100, and various components 1120 are physically or electrically connected to the motherboard 1110. In addition, other components that may or may not be physically or electrically connected to the motherboard 1110, such as a camera module 1130 and/or a speaker 1140, may be accommodated therein. Some of the electronic components 1120 may be the above-described chip related components, for example, a component package 1121, but are not limited thereto. The component package 1121 may be in the form of a printed circuit board on which electronic components including active components and/or passive components are surface mounted. Alternatively, the component package 1121 may be in the form of a printed circuit board in which active components and/or passive components are embedded. On the other hand, the electronic device is not necessarily limited to the smartphone 1100, and may also be other electronic devices as described above.

### Printed Circuit Board

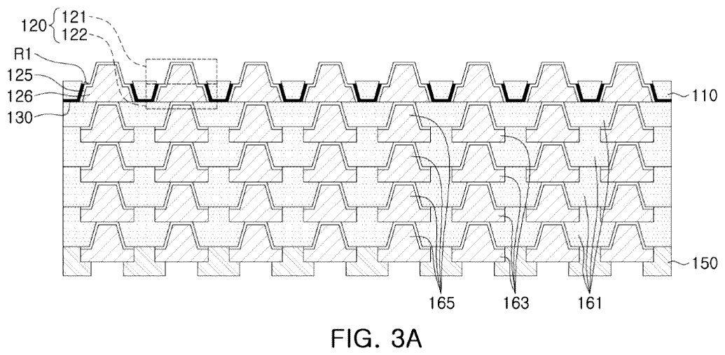

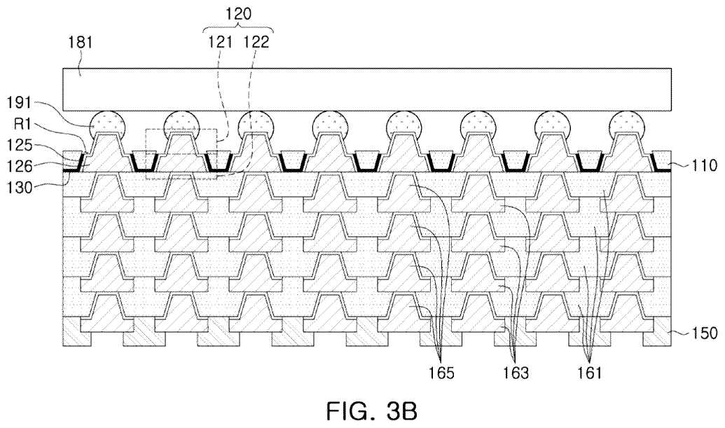

FIGS. 3A and 3B are cross-sectional views schematically illustrating a printed circuit board according to a first embodiment.

Referring to FIG. 3A, a printed circuit board according to the first embodiment may include a first insulating layer 110, a first metal layer 120 having a first portion 121 protruding above the first insulating layer 110 and a second portion 122 penetrating through the upper and lower surfaces of the first insulating layer 110, and a barrier layer 130 disposed at the boundary between the first insulating layer 110 and the second portion 122 and extending to the lower surface of the first insulating layer 110.

The first metal layer 120 may function as a means for connecting a printed circuit board to electronic components such as a semiconductor chip, or to other components such as a motherboard. Since the first metal layer 120 includes a first portion 121 protruding above the first insulating layer 110, connection with electronic components having a fine pitch may be performed more smoothly, and when forming an electrical connection path, defects due to a short circuit or separation of the connecting member may be prevented. In the printed circuit board according to the first embodiment, as the barrier layer 130 is disposed between the first metal layer 120 and the first insulating layer 110, in the operation of removing the temporary layer so that the first portion 121, which is a protruding area of the first metal layer 120, protrudes, defects in the first metal layer 120 may not occur. After the barrier layer 130 is disposed along the boundary of the through-hole of the temporary layer, the protruding portion is removed, and the barrier layer 130 may be disposed between the boundary of the first insulating layer 110 and the second portion 122 embedded in the first insulating layer 110 among the first metal layers 120, and may extend to the lower surface of the first insulating layer 110.

The printed circuit board according to the first embodiment is a so-called coreless board, and the first metal layer 120 disposed on the uppermost side thereof may be embedded in the first insulating layer 110. However, in the operation of forming the first metal layer 120, the barrier layer 130 is formed first to form the first portion 121, which is a protruding area, in the first metal layer 120. Even though it is a coreless substrate, the first metal layer 120 having a structure protruding above the first insulating layer 110 may be formed. To form a protrusion on a conventional coreless board, a separate metal layer was additionally formed on the outermost embedded pattern of the coreless board. However, the printed circuit board according to the first embodiment has a through-hole in the temporary layer. As the barrier layer 130 is disposed within, the first portion 121 and the second portion 122 of the first metal layer 120 may be formed integrally. Therefore, the printed circuit board according to the first embodiment may prevent the alignment problem of the protrusions having a fine pitch, and defects occurring at the interface between two metal layers, undercut defects, and defects occurring in a protruding relationship with the outermost insulating layer may not occur. This will be described in more detail later during the manufacturing stage.

The first insulating layer 110 may include an insulating material. Examples of the insulating materials may include thermosetting resins such as epoxy resins, thermoplastic resins such as polyimide, or materials containing these resins along with inorganic fillers, organic fillers, and/or glass fibers (Glass Fiber, Glass Cloth, and/or Glass Fabric). The insulating material may be a photosensitive material and/or a non-photosensitive material. For example, the insulating material of the first insulating layer 110 may be an insulating material of Ajinomoto Build-up Film (ABF), but is not limited thereto, and may also include Prepreg (PPG), Resin Coated Copper (RCC), a Photo Imageable Dielectric (PID), FR-4, Bismaleimide Triazine (BT), etc. However, the present disclosure is not limited thereto, and if necessary, other materials with excellent rigidity may be used.

The first metal layer 120 may include a metal material. The metal material may be copper (Cu), aluminum (Al), silver (Ag), tin (Sn), gold (Au), lead (Pb), titanium (Ti), or alloys thereof. The metal material may, in detail, include copper (Cu), but is not limited thereto. The first metal layer 120 may be an area for mounting electronic components and semiconductor chips, or may be an area for connection to a motherboard, etc. and may also be connected to a circuit pattern to perform signal connection with other pads. The first metal layer 120 may include a plurality of metal posts, but is not limited thereto and may further include a plurality of patterns and/or pads. Each metal post or pattern/pad of the first metal layer 120 may perform various functions depending on the design, and for example, may include a ground pattern/pad, a power pattern/pad, a signal pattern/pad, etc. In this case, the signal pattern/pad may include a pattern/pad for electrical connection of various signals other than ground, power, etc., for example, data signals. A plurality of metal posts may be formed simultaneously in the forming operation of the first metal layer 120, but the present disclosure is not limited thereto and may be formed sequentially or stepwise as needed. Additionally, the pattern/pad of the first metal layer 120 may electrically exchange signals with other patterns/pads, and may also perform a function thereof by being electrically short-circuited with other patterns/pads.

When the first metal layer 120 requires a high density and fine pitch for mounting electronic components such as semiconductor chips, the gap between each metal post and/or pattern of the first metal layer 120 may be narrowed, and in the case of mounting electronic components such as passive components, the gap between the first metal layers 120 may be wider.

The first metal layer 120 may be formed using any one of the Semi Additive Process (SAP), Modified Semi Additive Process (MSAP), Tenting (TT), and Subtractive methods, but is not limited thereto. As a non-limiting example, the first metal layer 120 may be formed by firing a paste containing a metal material. On the other hand, the method of forming the first metal layer 120 is not limited thereto, and may further include structures or methods that may be used by those skilled in the art. As a non-limiting example, the first metal layer 120 may include a seed layer 125 and a plating layer 126, respectively.

The seed layer 125 is disposed on the outermost surface of the first metal layer 120 and may be disposed along the top and side surfaces of the first metal layer 120, which may be the result of forming the seed layer 125 along the wall of the through-hole formed in the temporary layer and the first insulating layer 110. The seed layer 125 may function as a seed for forming the plating layer 126. The seed layer 125 may include, but is not limited to, an electroless plating layer (or chemical copper) formed through electroless plating, and may include a sputtering layer formed by sputtering instead of electroless plating, and may include both an electroless plating layer and a sputtering layer. However, the present disclosure is not limited thereto, and if necessary, any metal that may function as a seed for electroplating, such as copper foil, may be used without limitation.

The plating layer 126 is disposed on the seed layer 125 and may be formed using the seed layer 125 as a plating seed. The plating layer 126 may be formed to fill the through-hole formed in the temporary layer and the first insulating layer 110, and is formed on the seed layer 125 formed on the inner wall of the through-hole. The plating layer 126 is disposed on the seed layer 125 and may be formed toward the inside or bottom of the printed circuit board. The plating layer 126 may include an electroplating layer (or electroplating) formed through electroplating. However, the present disclosure is not limited thereto, and the plating layer 126 may be formed by firing a paste containing a metal material, and may not necessarily be formed by plating. In detail, the plating layer 126 is only intended to express that it is a separate metal layer that may be distinguished from the seed layer 125, and the method of forming the same is not necessarily limited by the text itself. Additional configurations or methods that may be used by those skilled in the art may be included.

The first metal layer 120 may include a first portion 121 protruding upward from the first insulating layer 110 and a second portion 122 embedded in the first insulating layer 110. The second portion 122 is an area penetrating through the upper and lower surfaces of the first insulating layer 110, the upper and lower surfaces of the second portion 122 may not be covered by the first insulating layer 110, and the side surface of the second portion 122 may be covered by the first insulating layer 110.

On the other hand, the boundaries of the first portion 121 and the second portion 122 are not clearly distinguishable. As a concept for distinguishing between the protruding part and the embedded part, the first portion 121 and the second portion 122 may be formed as one piece. For example, the seed layer 125 disposed on the outside of the first portion 121 extends outside the second portion 122, the seed layer 125 disposed in each region may be formed integrally, and the plating layer 126 disposed in the first portion 121 may also extend to the second portion 122 and be formed integrally with the plating layer 126 disposed in each region.

The first portion 121 is a protrusion of the first metal layer 120 and corresponds to an area formed by penetrating through the temporary layer disposed on the first insulating layer 110. As will be described later in the method of manufacturing a printed circuit board, the first portion 121 is a region of the first metal layer 120 formed inside the second through-hole penetrating through the temporary layer, and after the temporary layer is removed, the first portion 121 of the first metal layer 120 may form a region that protrudes beyond the first insulating layer 110.

The second portion 122 is an embedded part of the first metal layer 120 and corresponds to an area disposed within the first insulating layer 110. As will be described later in the method of manufacturing a printed circuit board, the second portion 122 has a first through-hole formed inside the first insulating layer 110, and the second portion 122 may be disposed within the first insulating layer. As the first through-hole is formed to penetrate the upper and lower surfaces of the first insulating layer 110, the second portion 122 of the first metal layer 120 may also be formed to penetrate the upper and lower surfaces of the first insulating layer 110.

The width of the lower surface of the first portion 121 may be narrower than the width of the upper surface of the second portion 122. After forming the first through-hole penetrating through the first insulating layer 110, a second through-hole penetrating through the temporary layer is formed, and the width of the second through-hole may be narrower than the width of the bottom surface of the first through-hole. Since the first portion 121 of the first metal layer 120 is formed to fill the second through-hole and the second portion 122 of the first metal layer 120 is formed to fill the first through-hole, the width of the lower surface of the first portion 121 may be narrower than the width of the upper surface of the second portion 122. As the first portion 121, which is a protrusion of the first metal layer 120, may be formed to be narrower than the second portion 122, which is an embedded part, a metal post with finer protrusions may be implemented.

The first portion 121 may have a shape tapered upwardly. That the first portion 121 has an upwardly tapered shape may mean that it has a substantially tapered shape so that the width of the upper surface of the first portion 121 is narrower than the width of the lower surface of the first portion 121. This is because the first portion 121 is formed to fill the second through-hole that penetrates the temporary layer, and thus the first portion 121 may have the same shape as the second through-hole. In the operation of forming the second through-hole through the temporary layer, the second through-hole is processed from the bottom to the top, so that the bottom surface may have a tapered shape to narrow the width, The first portion 121 may have a tapered shape so that the width of the upper surface is narrower than the width of the lower surface. However, the present disclosure is not necessarily limited thereto, and the first portion 121 may have a non-tapered shape so that the width of the lower surface and the upper surface are substantially the same.

The second portion 122 may also have a shape tapered upwardly. That the second portion 122 has an upwardly tapered shape may mean that it has a substantially tapered shape so that the width of the upper surface of the second portion 122 is narrower than the width of the lower surface of the second portion 122. This is because the second portion 122 is formed to fill the first through-hole penetrating through the first insulating layer 110, and thus the second portion 122 may have the same shape as the first through-hole. In the operation of forming the first through-hole through the first insulating layer 110, the first through-hole is processed from the bottom to the top to have a tapered shape so that the width of the bottom surface is narrowed. The second portion 122 may have a tapered shape so that the width of the upper surface is narrower than the width of the lower surface. However, the present disclosure is not necessarily limited thereto, and the second portion 122 may also have a non-tapered shape, and the width of the lower surface and the width of the upper surface may be substantially the same.

For example, the first portion 121 and the second portion 122 may each have a tapered shape, and at this time, the first portion 121 and the second portion 122 may have a shape tapered in substantially the same direction. In more detail, the first portion 121 and the second portion 122 may each have a shape tapered upwardly. Since the printed circuit board according to the first embodiment has a coreless structure and forms the first metal layer 120 to fill the second through-hole penetrating through the temporary layer, the first portion 121 and the second portion 122 of the first metal layer 120 may each have a shape tapered upwardly.

In the printed circuit board according to the first embodiment, the first metal layer 120 is formed to collectively fill the first and second through-holes that respectively penetrate different materials, and the first portion 121, which is a protruding part of the first metal layer 120, and the second portion 122, which is an embedded part, may have different widths. However, since the printed circuit board according to the first embodiment has a coreless structure and forms through-holes from the bottom to the top, the first portion 121 and the second portion 122 of the first metal layer 120 may each have a shape that is substantially tapered upwardly. This is different from the conventional method of performing multiple plating to have a coreless structure and a protruding structure, and it is a structural feature that occurs because a protrusion may be formed with single plating. By having this structure, problems such as alignment and deviation that occur between the protruding part and the embedded part may not occur.

On the other hand, in FIG. 3A, the degree of tapering of the first portion 121 and the degree of tapering of the second portion 122 are illustrated to be similar, but are not necessarily limited thereto. The degree to which the first portion 121 and the second portion 122 are tapered may be different. For example, the difference between the width of the upper surface and the lower surface of the first portion 121 may be less than the difference between the width of the upper surface and the width of the lower surface of the second portion 122, and in this case, the degree of tapering of the first portion 121 may be less than the degree of tapering of the second portion 122, and may have a lateral slope that is closer to vertical. This may correspond to the difference in shape that occurs in the formation stage of the second through-hole penetrating through the temporary layer and the first through-hole penetrating through the first insulating layer 110.

The printed circuit board according to the first embodiment may include a barrier layer 130 disposed at the boundary between the first insulating layer 110 and the second portion 122 of the first metal layer 120 and extending to the lower surface of the first insulating layer 110. The barrier layer 130 may be used as a means to separate the first metal layer 120, a temporary layer, as will be described later in a method of manufacturing a printed circuit board. After forming the first through-hole penetrating through the first insulating layer 110 and the second through-hole penetrating through the temporary layer, a barrier layer 130 is disposed on the lower surface of the first insulating layer 110 along the inside of the first and second through-holes, and then, the first metal layer 120 may be formed. In the subsequent operation in which the temporary layer is removed, the barrier layer 130 is configured to separate the temporary layer and the first metal layer 120, and may prevent the first metal layer 120 from being damaged when the temporary layer is removed.

The barrier layer 130 may include a different material from the first metal layer 120. The barrier layer 130 may be a thin oxide film containing metal oxide. The metal oxide may include at least one of Al₂O₃, SiO₂, TiO₂, ZnO, ZrO₂, HfO₂, and La₂O₃, but may also include a metal oxide doped with a different metal element. The metal oxide may in detail include alumina (Al₂O₃). On the other hand, the material of the barrier layer 130 is not necessarily limited to a metal oxide and may include metal materials with low reactivity, such as Pt and Ru.

The barrier layer 130 may be formed using a thin film deposition method, such as an Atomic Layer Deposition (ALD) method or a Molecular Vapor Deposition (MVD) method. As the barrier layer 130 is formed using a thin film deposition method, the barrier layer 130 may include an oxide film that is thinner than the first metal layer. As a non-limiting example, the barrier layer 130 may include a thin oxide film with a thickness of less than 0.1 μm, in detail, about 0.001 μm to 0.01 μm. On the other hand, in FIG. 3A, the barrier layer 130 is illustrated to have a similar thickness to the seed layer 125, but the present disclosure is not limited thereto. The seed layer 125 may be formed thicker than the barrier layer 130.

The barrier layer 130 is formed using a thin film deposition method, and may thus be formed conformally along the inner wall of the through-hole and the lower surface of the first insulating layer 110. For example, the barrier layer 130 may be disposed on the boundary between the first metal layer 120 and the first insulating layer 110 and extended to the lower surface of the first insulating layer 110. In more detail, the barrier layer 130 may be disposed at the boundary between the second portion 122, which is an embedded part of the first metal layer 120, and the first insulating layer 110. The barrier layer 130 may not be disposed on the upper surface of the second portion 122 of the first metal layer 120, and the barrier layer 130 may not be disposed on the first portion 121. This is because the method of manufacturing a printed circuit board includes removing a portion of the barrier layer 130 after removing a temporary layer to expose a portion of the first metal layer 120. For example, after removing the temporary layer so that the first metal layer 120 protrudes onto the first insulating layer 110, an operation of removing a portion of the barrier layer 130 is performed, which may be the result of removing a portion of the barrier layer 130 in an area not covered by the first insulating layer 110 among the barrier layer 130 disposed on the first metal layer 120. Accordingly, the barrier layer 130 may not be disposed on the upper surface of the first insulating layer 110, but may be disposed only on the lower surface of the first insulating layer 110, and the barrier layer 130 may be covered by the second insulating layer 161 on the lower side of the first insulating layer 110.

At this time, the first metal layer 120 may include a first recess R1 so as to have a step difference from the upper surface of the first insulating layer 110. In more detail, the upper surface of the second portion 122 of the first metal layer 120 and the upper surface of the first insulating layer 110 may have a step. The first recess R1 may correspond to a groove in which the second portion 122 of the first metal layer 120 is recessed from the upper surface of the first insulating layer 110. The first recess R1 may correspond to a trace where a portion of the barrier layer 130 has been removed. Since the barrier layer 130 is formed along the boundary of the first through-hole penetrating through the first insulating layer 110, the upper surface of the first insulating layer 110 may be disposed to be substantially coplanar with the barrier layer 130. Thereafter, as the barrier layer 130 in the area exposed from the first insulating layer 110 is removed, a first recess R1 may be formed in the second portion 122 of the first metal layer 120. Since the first recess R1 is formed by removing a portion of the barrier layer 130, the depth of the first recess R1 may be substantially the same as the thickness of the barrier layer 130. Since the first recess R1 is formed by removing a portion of the barrier layer 130, the upper surface of the second portion 122 of the first metal layer 120 may be substantially coplanar with the barrier layer 130. A portion of the barrier layer 130 exposed by the first recess R1 may substantially coplanar with the second portion 122.

The thickness of the barrier layer 130 may be measured by photographing a cross section cut in the stacking direction of the printed circuit board using a scanning microscope, etc. Since the barrier layer 130 has a thin film structure and may be conformally disposed along the outer surface of any structure, the thickness of the barrier layer 130 may be interpreted as the distance across the outer surface of the barrier layer, but may include measurement errors or errors in the manufacturing process. For example, the thickness of the barrier layer 130 may be an average value of the vertical distances of the barrier layer 130 measured at five arbitrary points. At this time, the depth of the first recess (R1) may mean the vertical distance from the extended surface of the upper surface of the first insulating layer 110 to the upper surface of the second portion 122 of the first metal layer 120, and may be measured by photographing a cut cross section in the stacking direction of the printed circuit board using a scanning microscope, etc.

On the other hand, the lower surface of a portion of the barrier layer 130 disposed on the lower surface of the first insulating layer 110 may substantially coplanar with the lower surface of the first metal layer 120. This may be the result of flattening the lower surface of the first metal layer 120 by removing a portion of the first metal layer 120 formed to extend onto the lower surface of the first insulating layer 110. In the operation of flattening the lower surface of the first metal layer 120 and removing unnecessary areas of the seed layer 125 and the plating layer 126 for patterning, the barrier layer 130 containing a different material from the first metal layer 120 may not be removed. Therefore, the lower surface of the barrier layer 130 disposed on the lower surface of the first insulating layer 110 and the lower surface of the first metal layer 120 may substantially coplanar.

At this time, since the lower surface of the first metal layer 120 is substantially coplanar with the barrier layer 130, the lower surface of the first metal layer 120 may protrude from the lower surface of the first insulating layer 110. At this time, since the lower surface of the first insulating layer 110 is not in direct contact with the first metal layer 120 and the barrier layer 130 is disposed between the first insulating layer 110 and the first metal layer 120, it may be understood that the lower surface of the first metal layer 120 protrudes from the extended surface of the lower surface of the first insulating layer 110. Because the lower surface of the barrier layer 130 formed on the lower surface of the first insulating layer 110 is substantially coplanar with the first metal layer 120, the lower surface of the first metal layer 120 may protrude from the lower surface of the first insulating layer 110, and the height of the protruding step may be substantially the same as the thickness of the barrier layer 130.

The printed circuit board according to the first embodiment may further include a second insulating layer 161 disposed below the first insulating layer 110, a first wiring layer 163 disposed on the second insulating layer 161, and a first via layer 165 penetrating at least a portion of the second insulating layer 161 to connect the first wiring layer 163 and the first metal layer 120 to each other.

The second insulating layer 161 may include an insulating material. The insulating material may include thermosetting resins such as epoxy resins, thermoplastic resins such as polyimide, or materials containing these resins along with inorganic fillers, organic fillers, and/or glass fibers (Glass Fiber, Glass Cloth, and/or Glass Fabric). The insulating material may be a photosensitive material and/or a non-photosensitive material. For example, the insulating material of the second insulating layer 161 may be an insulating material of Ajinomoto Build-up Film (ABF), but is not limited thereto, and may also include Prepreg (PPG), Resin Coated Copper (RCC), Photo Imageable Dielectric (PID), FR-4, Bismaleimide Triazine (BT), etc. However, the present disclosure is not limited thereto, and if necessary, other materials with excellent rigidity may be used. The second insulating layer 161 may include the same type of insulating material as the first insulating layer 110. The second insulating layer 161 may refer to a build-up layer like the first insulating layer. On the other hand, the second insulating layer 161 may be composed of a plurality of insulating layers, and the number and thickness of the layers may be any configuration that may be used by those skilled in the art.

When the first insulating layer 110 and the second insulating layer 161 are manufactured with substantially the same type of insulating material, the thickness of the first insulating layer 110 may be substantially the same as the thickness of the second insulating layer 161. On the other hand, the present disclosure is not necessarily limited thereto, and the thickness of the first insulating layer 110 may be formed to be thinner than the thickness of the second insulating layer 161. Because the second portion 122 penetrating through the first insulating layer 110 among the first metal layers 120 may correspond to a pad, to penetrate the upper and lower surfaces of the first insulating layer 110, the thickness of the first insulating layer 110 may be formed to be thinner. In addition, in order for the first metal layer 120 to function as a pattern, it may be patterned by penetrating through the first insulating layer 110 to form a finely structured wiring to connect adjacent second portions. The first insulating layer 110 may be implemented with a thin thickness. On the other hand, the present disclosure is not limited thereto, and the thickness of the first insulating layer 110 may be thicker than the thickness of the second insulating layer 161. Since the first insulating layer 110 is the first insulating layer formed in the coreless substrate, rigidity may be secured by forming the same thicker than other insulating layers. In FIG. 3A, the first insulating layer 110 and the second insulating layer 161 are illustrated to have substantially the same thickness, but this is not necessarily limited. The thickness of the first insulating layer 110 and the thickness of the second insulating layer 161 may be designed in various manners.

The first wiring layer 163 may include a metal material. The metal material may be copper (Cu), aluminum (Al), silver (Ag), tin (Sn), gold (Au), lead (Pb), titanium (Ti), or alloys thereof. The metal material may in detail include copper (Cu), but is not limited thereto. The first wiring layer 163 may include a plurality of patterns, and each may perform various functions depending on the design, and for example, may include a ground pattern, power pattern, signal pattern, etc. In this case, the signal pattern may include patterns for electrical connection of various signals other than ground, power, etc., for example, data signals. The first wiring layer 163 may include an electroless plating layer (or chemical copper) and an electrolytic plating layer (or electrical copper), but is not limited thereto. A sputtering layer may be formed instead of the electroless plating layer, and both may be included. Additionally, it may further include copper foil.

Each of the first via layers 165 may include micro vias. Micro vias may be field vias that fill a via hole or conformal vias arranged along the wall of the via hole. Micro vias may be arranged as a stacked type and/or a staggered type. Each first via layer 165 may include a metal, and the metals may include copper (Cu), aluminum (Al), silver (Ag), tin (Sn), gold (Au), nickel (Ni), lead (Pb), titanium (Ti), or alloys thereof, and in detail, may include copper (Cu), but is not limited thereto. The first via layer 165 may include an electroless plating layer (or chemical copper) and an electrolytic plating layer (or electrolytic copper), but is not limited thereto. A sputtering layer may be formed instead of the electroless plating layer, and both may be included. The first via layer 143 may perform various functions depending on the design of each layer, and for example, may include ground vias, power vias, signal vias, etc.

As the number of layers of the second insulating layer 161 may vary, the first wiring layer 163 disposed on the second insulating layer 161 and the first via layer 165 penetrating at least a portion of the second insulating layer 161 may also have various numbers of layers.

On the other hand, when the depths of the plurality of second insulating layers 161 are substantially the same, among the plurality of first via layers 165, the first via layer 165 in contact with the first metal layer 120 may be deeper than the remaining first via layers 165. This is because the lower surface of the first metal layer 120 is substantially coplanar with the upper surface of the second insulating layer 161, and this is because the first via layer 165 in contact with the first metal layer 120 has a via depth that is substantially the same as the thickness of the second insulating layer 161. Since each of the first via layers 165 other than the first via layer 165 in contact with the first metal layer 120 is connected to the first wiring layer 163 protruding on the lower surface of the second insulating layer 161, the depth of the first via layer 165 may be smaller than the thickness of the second insulating layer 161, and the thickness of the first wiring layer 163 and the depth of the first via layer 165 may be substantially the same as the thickness of the second insulating layer 161. This is a configuration in which the first metal layer 120 is embedded in the first insulating layer 110, and this is because the first metal layer 120 only has a step equal to the thickness of the barrier layer 130 below the first insulating layer 110 and does not have a protruding structure.

On the other hand, the printed circuit board according to the first embodiment may further include a solder resist layer 150 disposed below the second insulating layer 161. For example, the printed circuit board according to the first embodiment may further include a solder resist layer 150 on the lowermost side. The solder resist layer 150 may include an insulating material and may include, but is not limited to, a liquid or film type solder resist. Other types of insulating materials may also be used. The solder resist layer 150 may have an opening that exposes at least a portion of the first wiring layer 163. A portion of the first wiring layer 163 exposed through the opening may later function as a pad for connection to other components such as the main board, but is not necessarily limited thereto.

Referring to FIG. 3B, the printed circuit board according to the first embodiment may further include a first connecting member 191 disposed on the first metal layer 120 and a first electronic component 181 disposed on the first connecting member 191 and connected to the first metal layer 120.

The first electronic component 181 may include a semiconductor chip, and the semiconductor chip may be an integrated circuit (IC) in which hundreds to millions of chips are integrated into one chip. The semiconductor chips may be processor chips such as central processors (e.g., CPUs), graphics processors (e.g., GPUs), field programmable gate arrays (FPGAs), digital signal processors, cryptographic processors, microprocessors, and microcontrollers, in detail, application processors (APs), but are not limited thereto. The semiconductor chips may be a logic chip, such as an analog-to-digital converter, an application-specific IC (ASIC) memory controller (MC) chip, or the like, or may be a memory chip, such as, a Dynamic Random Access Memory (DRAM) chip, a Static Random Access Memory (SRAM) chip, a flash memory chip, a Phase-change Random Access Memory (PRAM) chip, a Magnetic Random Access (MRAM) chip, a Resistive Random Access Memory (RRAM) chip, an Electrically Erasable and Programmable Read-Only Memory (EEPROM) chip, a High Bandwidth Memory (HBM), or the like, which may also be disposed in combination with each other.

On the other hand, the first electronic component 181 is not necessarily limited to a semiconductor chip, and may be in the form of a package including the same. On the other hand, as a non-limiting example, the first electronic component 181 may include passive elements such as capacitors and/or inductors, and may also include passive elements in the form of chips.

The first electronic component 181 may include a body and a pad, and the side on which the pad for connection to the first metal layer 120 is disposed may be an active side, and the opposite side may be an inactive side. The first electronic component 181 may be formed based on an active wafer, and in this case, silicon (Si), germanium (Ge), gallium arsenide (GaAs), etc. may be used as the base material forming the body. Various circuits may be formed on the body of the first electronic component 181.

The first connecting member 191 may be disposed on the first metal layer 120 to connect the first electronic component 181 and the first metal layer 120 to each other. The first connecting member 191 may be disposed on the upper surface of the first portion 121 of the first metal layer 120 and may be arranged to cover at least a portion of the side surface of the first portion 121. The first connecting member 191 may include a conductive material, for example, a solder composed of tin (Sn)-silver (Ag), or may include copper (Cu). On the other hand, the first connecting member 191 is not limited thereto and may further include aluminum (Al). On the other hand, the material of the first connecting member 191 is not limited thereto and may further include materials that may be used by those skilled in the art.

The printed circuit board according to the first embodiment is not limited to the configuration illustrated in FIGS. 3A and 3B, and other components may be further included, or may be omitted in some cases, and in detail, may include additional configurations that may be used by anyone with ordinary knowledge in the relevant technical field.

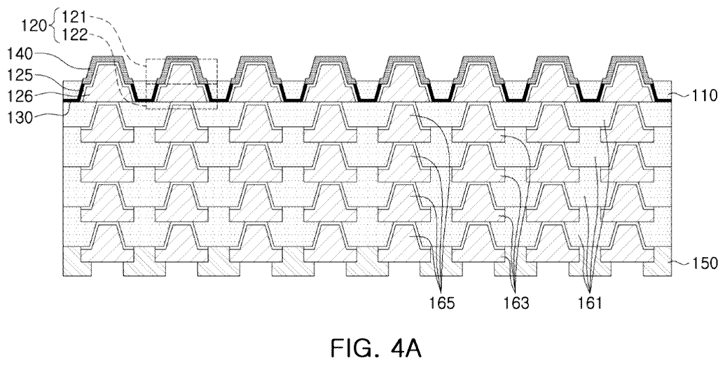

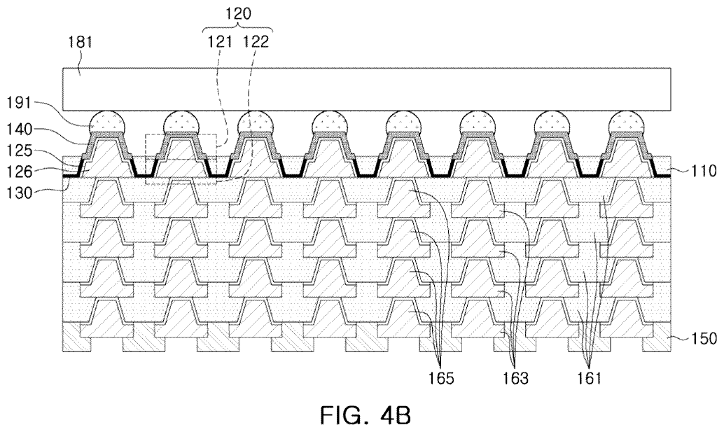

FIGS. 4A and 4B are cross-sectional views schematically illustrating a printed circuit board according to a second embodiment.

Referring to FIGS. 4A and 4B, the printed circuit board according to the second embodiment may further include a surface treatment layer 140 disposed on the first metal layer 120. The surface treatment layer 140 is disposed on the first metal layer 120 and may be formed to cover the surface of the first metal layer 120 exposed from the first insulating layer 110. For example, the surface treatment layer 140 may cover the first portion 121 of the first metal layer 120 and the upper surface of the second portion 122. For example, the surface treatment layer 140 may be formed in an area in which a portion of the barrier layer 130 has been removed, and a portion of the barrier layer 130 may be formed to fill the first recess R1 of the removed first metal layer 120.

The surface treatment layer 140 may include any one of nickel (Ni), palladium (Pd), and gold (Au), and a plurality of these metal layers may be implemented. For example, the surface treatment layer 140 may be at least a portion of an ENEPIG (Electroless Nickel Electroless Palladium Immersion Gold) structure, or may be at least a portion of an Electroless Nickel Immersion Gold (ENIG) structure. The surface treatment layer 140 is not limited thereto, and may include an organic solder passivation (OSP) structure containing an organic material. The surface treatment layer 140 may improve adhesion and signal transmission between the first metal layer 120 and the first connecting member 191. In FIGS. 4A and 4B, the surface treatment layer 140 is illustrated as consisting of one layer, but the present disclosure is not limited thereto. The surface treatment layer 140 may be implemented as a plurality of metal layers as described above.

The thickness of the surface treatment layer 140 may be thicker than the thickness of the barrier layer 130. As described above, the barrier layer 130 may be an oxide film formed by surface deposition, but the surface treatment layer 140 is a plating layer formed by electroless plating and may include a plurality of metal layers. The surface treatment layer 140 may be thicker than the barrier layer 130 including a thin oxide film. Accordingly, the surface treatment layer 140 may be arranged to protrude from the upper surface of the first insulating layer 110 while filling the first recess R1 from which a portion of the barrier layer 130 was removed.

On the other hand, the same configurations as those of the printed circuit board according to other embodiments, other than those related to the surface treatment layer 140, may also be applied to the printed circuit board according to the second embodiment, and thus duplicate descriptions thereof will be omitted.

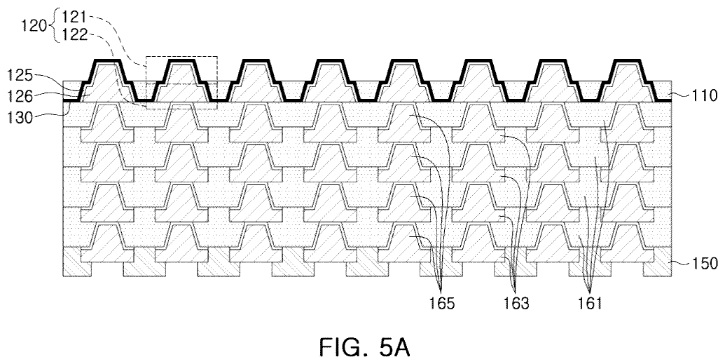

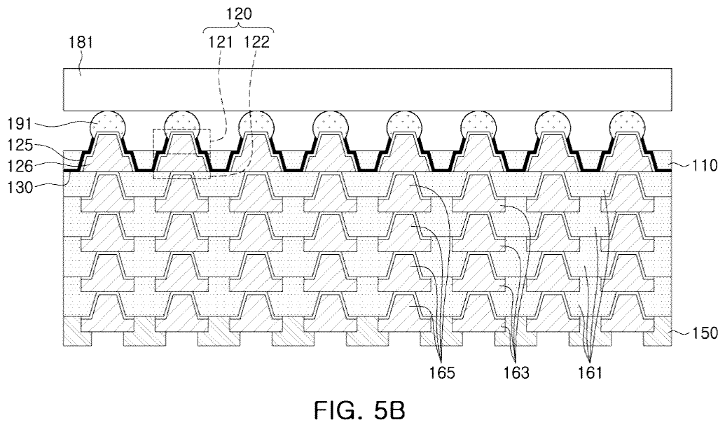

FIGS. 5A and 5B are cross-sectional views schematically illustrating a printed circuit board according to a third embodiment.

Referring to FIG. 5A, in the printed circuit board according to the third embodiment, the barrier layer 130 covers at least a portion of the first portion 121 of the first metal layer 120, and the side of the second portion 122 may be arranged to cover substantially the entire side. For example, the barrier layer 130 is not only disposed at the boundary between the second portion 122 of the first metal layer 120 and the first insulating layer 110, and the barrier layer 130 may be arranged to cover at least a portion of the first portion 121 and the upper surface of the second portion 122. In addition, the barrier layer 130 covers the top and side surfaces of the first portion 121, so that the barrier layer 130 may cover substantially the entire first portion 121 of the first metal layer 120.

This is so that the method of manufacturing a printed circuit board does not include the operation of removing part of the barrier layer 130 after the operation of removing the temporary layer. This may be the result of arranging the barrier layer 130 to cover the first metal layer 120. The barrier layer 130 may be disposed along the outside of the first metal layer 120, and in detail, may be disposed along the seed layer 125 of the first metal layer 120. This may be the result of being disposed along the inner wall of the first through-hole penetrating through the first insulating layer 110 and the second through-hole penetrating through the temporary layer.

Referring to FIG. 5B, in the printed circuit board according to the third embodiment, the barrier layer 130 may not be disposed in the area in which the first connection member 191 is disposed. This may be the result of a portion of the barrier layer 130 being removed from the area in which the first connecting member 191 and the barrier layer 130 are in contact as the first connecting member 191 is disposed. The first connecting member 191 may be disposed on the upper side of the first portion 121, arranged to cover at least a portion of the upper surface of the first portion 121 and arranged to cover at least part of the side of the first portion 121.

The barrier layer 130 may be an oxide film containing a metal oxide or an oxide of a first metal. This may be the case when the first connecting member 191 includes a metal of the same element as the metal material of the barrier layer 130, for example, when the first connecting member 191 includes the first metal. In detail, the first metal may be aluminum (Al), the first connecting member 191 may include a conductive material containing aluminum (Al), and the barrier layer 130 may include alumina (Al₂O₃), an oxide containing aluminum (Al), but the type of first metal is not necessarily limited thereto. When the first connecting member 191 and the barrier layer 130 contain the same first metal element, in the area in which the barrier layer 130 and the first connecting member 191 come into contact, the first metal present in the barrier layer 130 diffuses into the first connecting member 191. Part of the barrier layer 130 may be removed. For example, as part of the barrier layer 130 is removed, the first metal layer 120 and the first connecting member 191 may come into contact, and therefore, the first metal layer 120 and the first electronic component 181 may be electrically connected through the first connection member 191. Accordingly, the barrier layer 130 may cover a portion of the first portion 121, but may have a structure in which the barrier layer 130 is not disposed in the area in which the first portion 121 and the first connecting member 191 are in contact.

For example, the case in which the barrier layer 130 covers the entirety of the first metal layer 120 as illustrated in FIG. 5A and the case in which the barrier layer 130 is not disposed on the first portion 121 in contact with the first connecting member 191 may both correspond to the printed circuit board according to the third embodiment, which do not contradict each other as described above.

On the other hand, among the configurations other than the content regarding the arrangement of the barrier layer 130 and the arrangement of the first connecting member 191 and the arrangement relationship of the barrier layer 130, since the same configuration as the printed circuit board according to other embodiments may also be applied to the printed circuit board according to the third embodiment, redundant descriptions related thereto will be omitted.

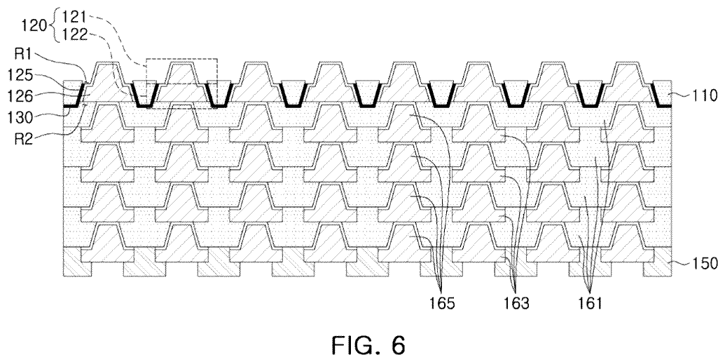

FIG. 6 is a cross-sectional view schematically illustrating a printed circuit board according to a fourth embodiment.

Referring to FIG. 6, the printed circuit board according to the fourth embodiment may have a step between the lower surface of the first metal layer 120 and the lower surface of the barrier layer 130. For example, the lower surface of the first metal layer 120 may have a second recess (R2), and the second recess (R2) may be filled with the second insulating layer 161. The second recess (R2) may be the result of over-etching the first metal layer 120 during the patterning operation of removing a portion of the seed layer 125 and the plating layer 126, in the operation of forming the first metal layer 120. Since the barrier layer 130 includes a different material from the first metal layer 120, the barrier layer 130 and the second insulating layer 161 are not removed in the operation of removing part of the first metal layer 120, and only a portion of the first metal layer 120 may be removed. At this time, the lower surface of the first metal layer 120 may be removed more than the lower surface of the barrier layer 130 to form the second recess R2. At this time, the depth of the second recess R2 may be thicker than the thickness of the barrier layer 130, and in this case, the lower surface of the first metal layer 120 may have a recessed structure than the extended surface of the lower surface of the first insulating layer 110.

On the other hand, the same configuration as that of the printed circuit board according to other embodiments, other than the content related to the second recess R2 formed on the lower surface of the first metal layer 120, may be applied to the printed circuit board according to the fourth embodiment. Therefore, redundant explanation regarding this will be omitted.

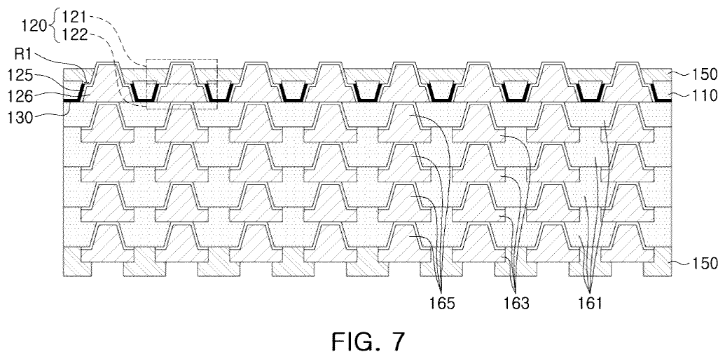

FIG. 7 is a cross-sectional view schematically illustrating a printed circuit board according to a fifth embodiment.

Referring to FIG. 7, the printed circuit board according to the fifth embodiment may further include a solder resist layer 150 disposed on the first insulating layer 110. The description of the solder resist layer 150 disposed on the upper side of the first insulating layer 110 may be applied to the description of the solder resist layer 150 disposed on the lower side of the second insulating layer 161, and thus the redundant description is omitted, and only the relationship between the solder resist layer 150, the first metal layer 120, and the barrier layer 130 will be described.

The solder resist layer 150 may be disposed on the upper surface of the first insulating layer 110 and cover at least a portion of the first metal layer 120. The solder resist layer 150 may cover a portion of the side surface of the first portion 121 of the first metal layer 120, and the remaining part of the side surface of the first portion 121 may protrude from the solder resist layer 150. For example, the upper surface of the first portion 121 of the first metal layer 120 may be disposed to protrude beyond the upper surface of the solder resist layer 150. This may be understood as the first metal layer 120 protruding through the solder resist layer 150. Since the upper surface of the first portion 121 of the first metal layer 120 protrudes beyond the solder resist layer 150, the first metal layer 120 of the printed circuit board may be electrically connected to electronic components and the like. Since the solder resist layer 150 may be formed after removing a portion of the barrier layer 130 disposed on the first metal layer 120, the solder resist layer 150 may be disposed to be in direct contact with a portion of the first metal layer 120.

On the other hand, among the components other than the solder resist layer 150 disposed on the upper surface of the first insulating layer 110, since the same configuration as the printed circuit board according to the other embodiments may be applied to the printed circuit board according to the fifth embodiment, redundant descriptions related thereto will be omitted.

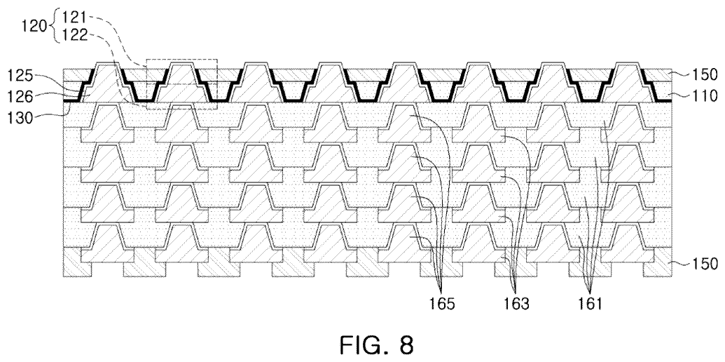

FIG. 8 is a cross-sectional view schematically illustrating a printed circuit board according to a sixth embodiment.

Referring to FIG. 8, the printed circuit board according to the sixth embodiment may further include a solder resist layer 150 disposed on the first insulating layer 110, and the barrier layer 130 may be arranged to extend between the first metal layer 120 and the solder resist layer 150. The printed circuit board is manufactured after the first metal layer 120 is exposed to the outside of the first insulating layer 110 by removing the temporary layer in the manufacturing method of the printed circuit board and by performing the operation of forming the solder resist layer 150 before removing part of the barrier layer 130, and the barrier layer 130 disposed between the first metal layer 120 and the solder resist layer 150 may remain, and only the barrier layer 130 disposed in the protruding area that is not covered by the solder resist layer 150 is removed, thereby exposing a portion of the first portion 121 of the first metal layer 120. Because a portion of the first portion 121 of the first metal layer 120 is exposed so that the upper surface of the first portion 121 protrudes beyond the solder resist layer 150, the first metal layer 120 of the printed circuit board may be electrically connected to electronic components, etc.

On the other hand, among the configurations other than the arrangement of the solder resist layer 150 disposed on the upper surface of the first insulating layer 110 and the resulting barrier layer 130, since the configurations that are the same as those of the printed circuit board according to other embodiments may also be applied to the printed circuit board according to the sixth embodiment, redundant descriptions related thereto will be omitted.

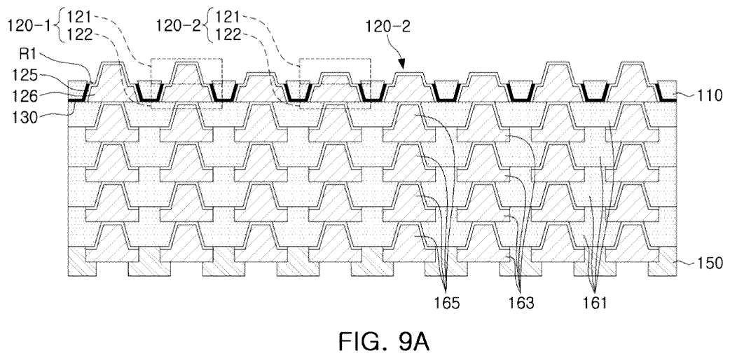

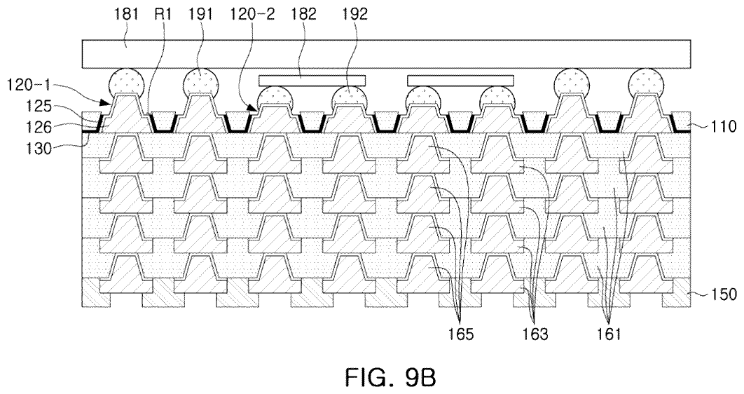

FIGS. 9A and 9B are cross-sectional views schematically illustrating a printed circuit board according to a seventh embodiment.

Referring to FIG. 9A, in the printed circuit board according to the seventh embodiment, the first metal layer may include a first metal post 120-1 and a second metal post 120-2, and the thickness of the first metal post 120-1 may be thicker than the thickness of the second metal post 120-2. The first metal post 120-1 and the second metal post 120-2 may respectively correspond to the first portion 121, which is a protrusion of the first metal layer 120 as previously described. This may be the result of forming through-holes with different depths in the operation of forming the second through-hole penetrating through the temporary layer in the printed circuit board manufacturing method. Because the depths of the second through-holes are different from each other, the thickness of the first metal post 120-1 may be thicker than the thickness of the second metal post 120-2. At this time, at least a portion of the second through-hole does not penetrate the temporary layer and may be the result of only a portion of the temporary layer being removed, and in this case, the second through-hole may correspond to a recess from which part of the temporary layer has been removed or a hole that penetrates only part of the temporary layer. The thickness of the first metal post 120-1 and the thickness of the second metal post 120-2 may be measured by imaging a cross section cut in the stacking direction of the printed circuit board using a scanning microscope or the like. The thickness of a component may be interpreted as the distance across the component vertically, but may include measurement errors or errors in the manufacturing process. For example, the thickness of the first metal post 120-1 may be an average value of the vertical distance between the lower surface and the upper surface of the first metal post 120-1 measured at five arbitrary points with respect to one first metal post 120-1. The thickness of the second metal post 120-2 may also be measured and compared in the same manner.

Referring to FIG. 9B, the printed circuit board according to the seventh embodiment may further include a first connecting member 191 disposed on the first metal post 120-1 and a first electronic component 181 disposed on the first connecting member 191 and connected to the first metal post 120-1, and may further include a second connecting member 192 disposed on the second metal post 120-2 and a second electronic component 182 disposed on the second connecting member 192 and connected to the second metal post 120-2.

In the same spirit as the first electronic component 181, the second electronic component 182 may include a semiconductor chip, and the semiconductor chip may be an integrated circuit (IC) in which hundreds to millions of chips are integrated into one chip. On the other hand, the second electronic component 182 is not necessarily limited to a semiconductor chip, and may be in the form of a package including the same. On the other hand, as a non-limiting example, the second electronic component 182 may include passive elements such as capacitors and/or inductors, and may also include passive elements in the form of chips. In the same sense as the first connecting member 191, the second connecting member 192 may include a conductive material. Since the description of the second electronic component 182 and the second connecting member 192 may be applied to the description of the first electronic component 181 and the first connecting member 191, overlapping content will be omitted.

The second electronic component 182 may have a thickness thinner than that of the first electronic component 181, but is not necessarily limited thereto. Because the second metal post 120-2 on which the second electronic component 182 is disposed is thinner than the first metal post 120-1, the second electronic component 182 may have a thinner thickness than the first electronic component 181. Additionally, in detail, the second electronic component 182 may be disposed below the first electronic component 181. For example, the second electronic component 182 may be disposed between the first electronic component 181 and the first metal post 120-1. This is because the second metal post 120-2 is formed to be thinner than the first metal post 120-1, using the height difference that occurs between the first metal post 120-1 and the second metal post. Since the second electronic component 182 may be mounted, the overall thickness of the printed circuit board may be reduced, while electronic components may be mounted more efficiently.

On the other hand, among the configurations other than the information regarding the shape of the first metal layer and the information regarding the second electronic component 182 and the second connecting member 192, since the same configuration as the printed circuit board according to the other embodiments may also be applied to the printed circuit board according to the seventh embodiment, redundant description related thereto will be omitted.

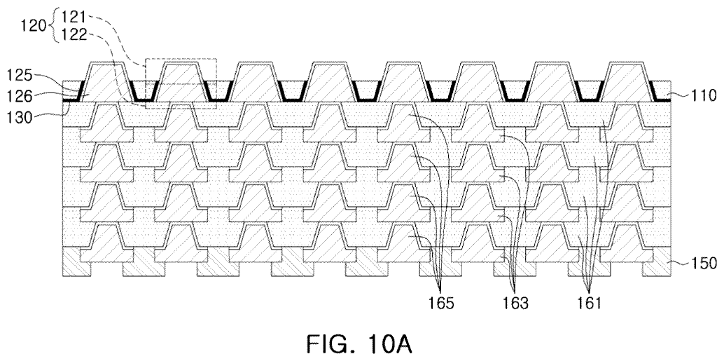

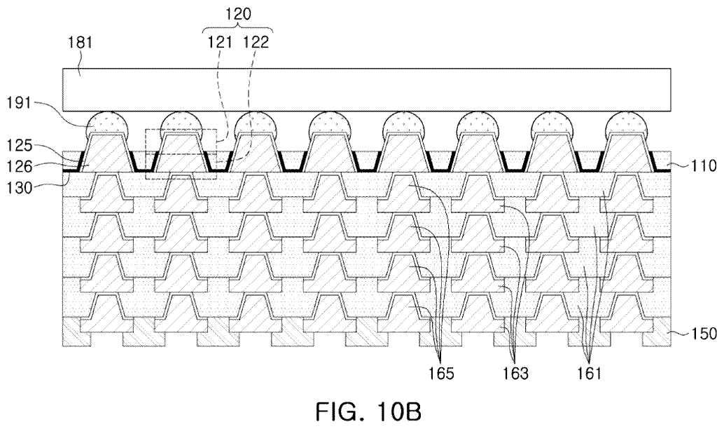

FIGS. 10A and 10B are cross-sectional views schematically illustrating a printed circuit board according to an eighth embodiment.

Referring to FIGS. 10A and 10B, in the printed circuit board according to the eighth embodiment, the lower surface of the first portion 121 and the upper surface of the second portion 122 of the first metal layer 120 may have substantially the same width, and the first metal layer 120 may have a tapered shape so that the width becomes narrower toward the top. This may be the result of forming a first through-hole penetrating through the first insulating layer 110 and a second through-hole penetrating through the temporary layer simultaneously in the method of manufacturing a printed circuit board. In the operation of forming the through-hole, the through-hole forming step may be reduced by considering the material of the first insulating layer 110 and the temporary layer and the depth of the through-hole. Therefore, the boundary between the first portion 121 and the second portion 122 of the first metal layer 120 may not be clear, and the first metal layer 120 may have a tapered shape as it moves upward. On the other hand, in FIGS. 10A and 10B, the first portion 121 and the second portion 122 of the first metal layer 120 are illustrated as having a tapered shape so as to have substantially the same inclination. The present disclosure is not necessarily limited thereto, and the degree of taper of the first portion 121 and the second portion 122 may be different. However, even in this case, since the through-hole is formed from the bottom to the top based on the drawing, the first metal layer 120 may have a shape tapered upwardly so that the width of the upper surface is narrower than the width of the lower surface.

On the other hand, the same configuration as that of the printed circuit board according to other embodiments, other than the shape of the first metal layer 120, may also be applied to the printed circuit board according to the eighth embodiment, and thus duplicate descriptions thereof are omitted.

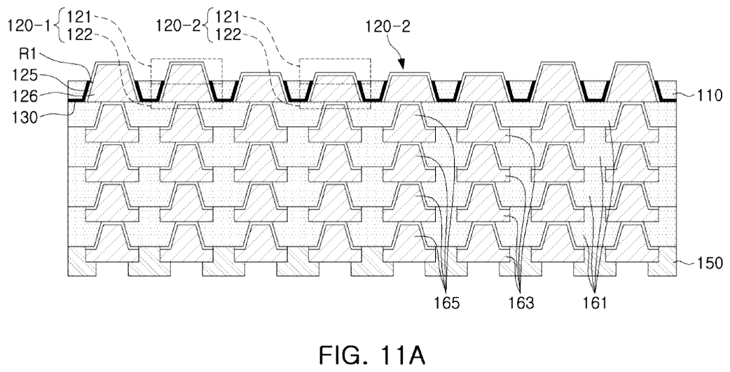

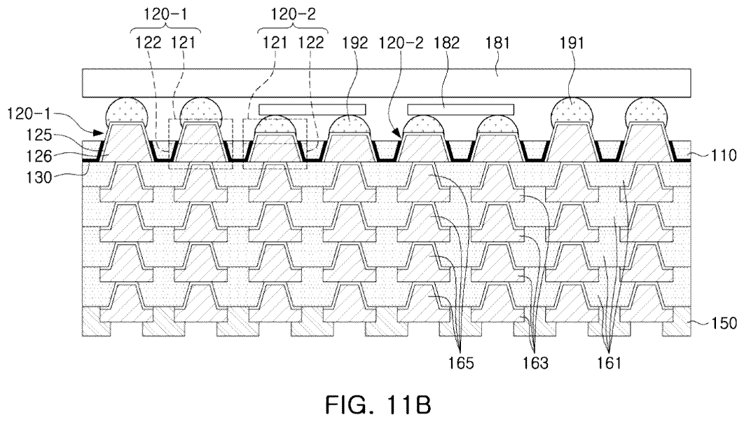

FIGS. 11A and 11B are cross-sectional views schematically illustrating the printed circuit board according to a ninth embodiment.

Referring to FIGS. 11A and 11B, in the printed circuit board according to the eighth embodiment, the first metal layer may include a first metal post 120-1 and a second metal post 120-2, and the lower surface of the first portion 121 and the upper surface of the second portion 122 of each metal post may have substantially the same width. The thickness of the first metal post 120-1 may be smaller than the thickness of the second metal post 120-2. The first metal post 120-1 and the second metal post 120-2 may respectively correspond to the first portion 121, which is a protrusion of the first metal layer 120 as previously described. This shape is the result of simultaneously forming a first through-hole penetrating through the first insulating layer 110 and a second through-hole penetrating through the temporary layer in the printed circuit board manufacturing method, and this may be the result of a plurality of integrally formed through-holes being formed at different depths so that each has a step difference. In this case as well, as described above, the plurality of through-holes may not completely penetrate the temporary layer and may be recesses or holes in which only part of the temporary layer is removed.

On the other hand, the same configuration as that of the printed circuit board according to other embodiments, other than the shape of the first metal layer, may also be applied to the printed circuit board according to the ninth embodiment, and thus duplicate descriptions thereof are omitted.

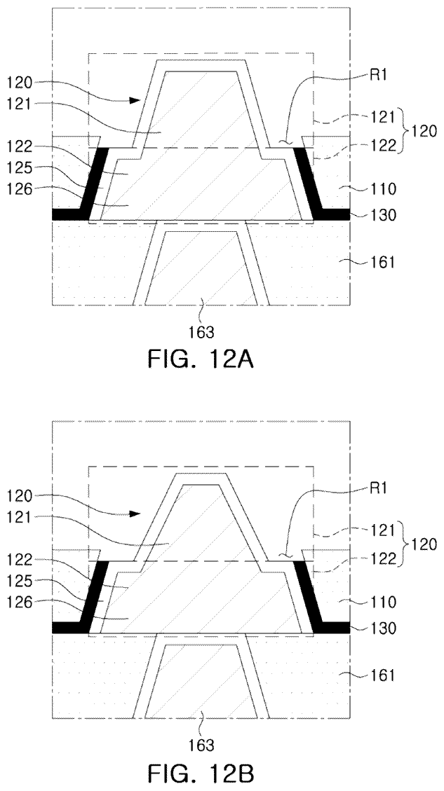

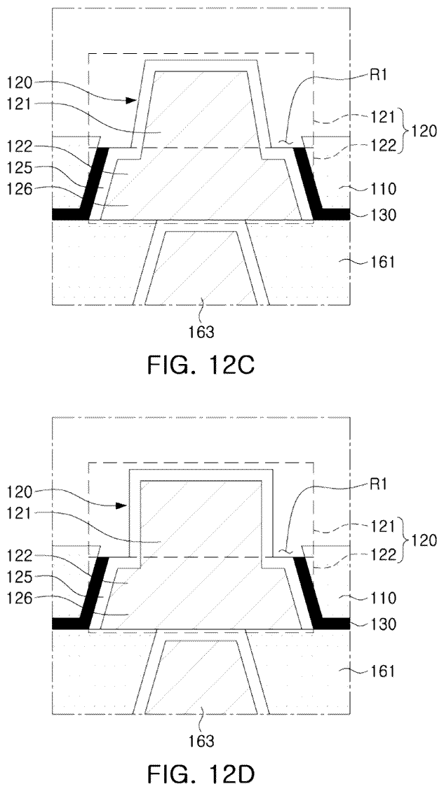

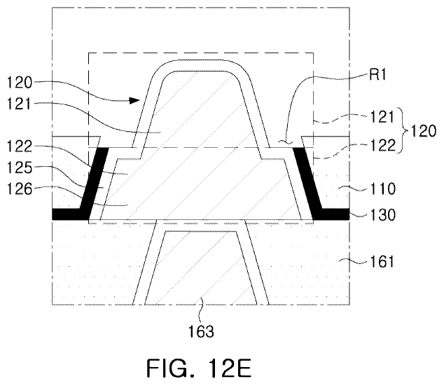

FIGS. 12A to 12E are cross-sectional views schematically illustrating various shapes of the first metal layer of the printed circuit board.

Referring to FIGS. 12A to 12E, the width of the lower surface of the first portion 121 may be narrower than the width of the upper surface of the second portion 122. This may be the result of forming a second through-hole penetrating through the temporary layer after forming the first through-hole penetrating through the first insulating layer 110.

Referring to FIG. 12A, the degree of tapering of the first portion 121 may be substantially the same as the degree of tapering of the second portion 122.

Referring to FIG. 12B, the degree of tapering of the first portion 121 may be greater than the degree of tapering of the second portion 122. The fact that the degree of tapering of the first portion 121 is greater than the degree of tapering of the second portion 122 may mean that the change in width of the upper and lower surfaces of the first portion 121 is greater than the change in the width of the upper and lower surfaces of the second portion 122. The slope of the side of the first portion 121 may be closer to horizontal than the slope of the side of the second portion 122, which may mean that the slope of the side of the second portion 122 may be closer to vertical than the slope of the side of the first portion 121.

Referring to FIG. 12C, the degree of tapering of the first portion 121 may be smaller than the degree of tapering of the second portion 122. The fact that the degree of tapering of the first portion 121 is less than the degree of tapering of the second portion 122 may mean that the degree of tapering of the second portion 122 is greater than the degree of tapering of the first portion 121.

Referring to FIG. 12D, the first portion 121 may be formed not to be tapered, and the width of the upper surface and the width of the lower surface of the first portion 121 may be substantially the same.

Referring to FIG. 12E, the first portion 121 may have a curved surface on the upper side.

The shape of the first metal layer 120 illustrated in FIGS. 12A to 12E is merely illustrative. The shape of the first metal layer 120 may be designed in various manners, depending on the conditions for forming the through-hole, such as the processing method, degree of processing, and time in the operation of forming the first through-hole penetrating through the first insulating layer 110 and the operation of forming the second through-hole penetrating through the temporary layer. The shape of the first portion 121, which is a protrusion of the first metal layer 120, may be varied depending on the type and design of electronic components, etc. disposed on the first metal layer 120, and by varying the shape of the first metal layer 120, reliability may be secured when mounting electronic components.

On the other hand, the shape of the first metal layer is not limited to the examples illustrated in FIGS. 12A to 12E, and anyone with ordinary knowledge in the relevant technical field may include all configurations or shapes using methods that may be used. In addition, the various shapes of the first metal layer 120 are not limited to the printed circuit board according to the first embodiment, and can, of course, be applied to printed circuit boards according to other embodiments.

### Method of Manufacturing Printed Circuit Board

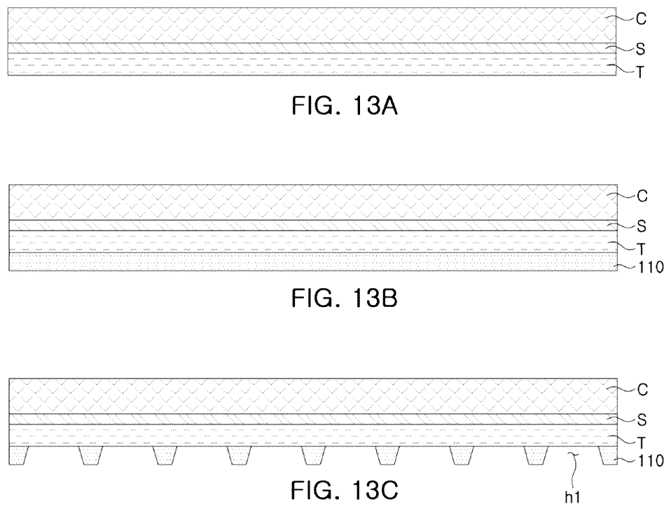

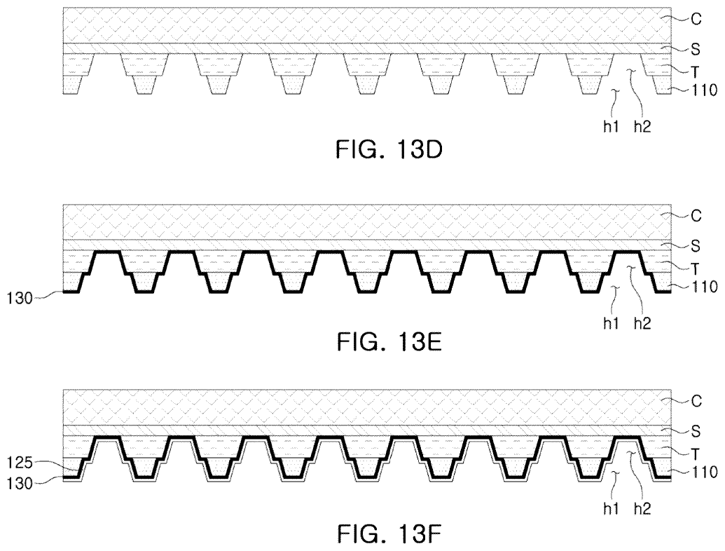

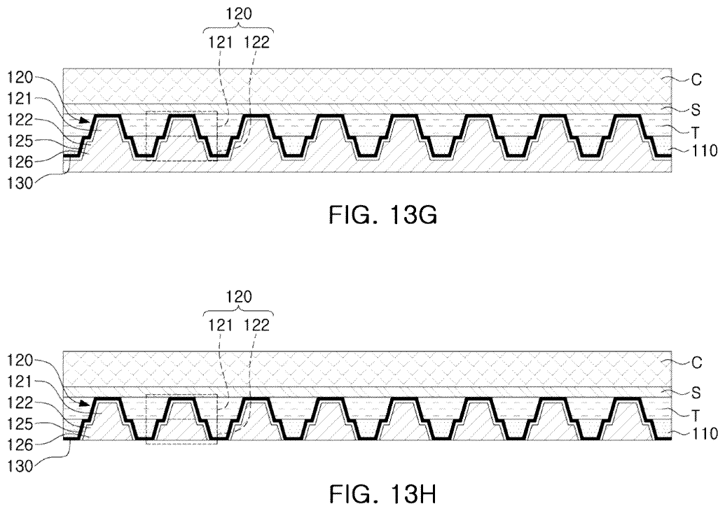

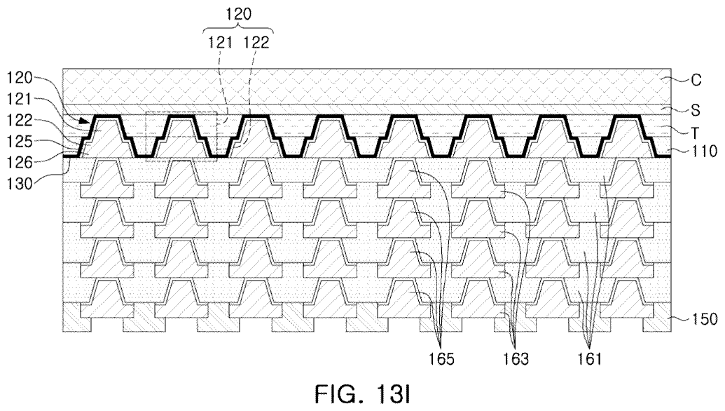

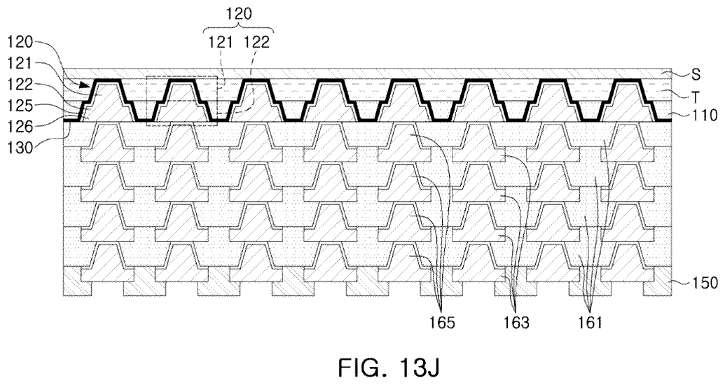

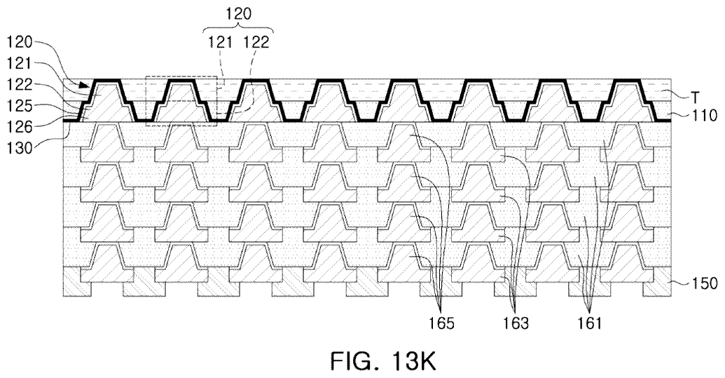

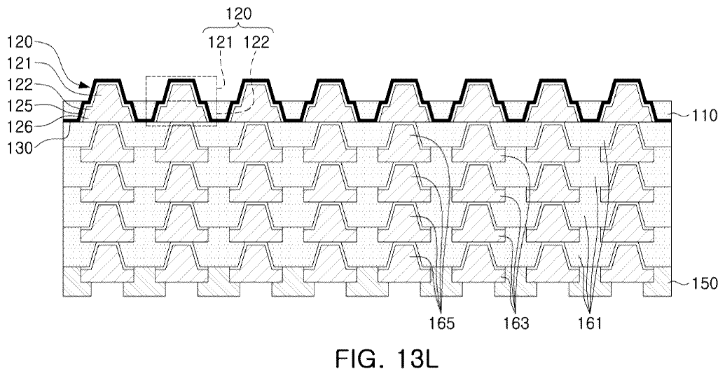

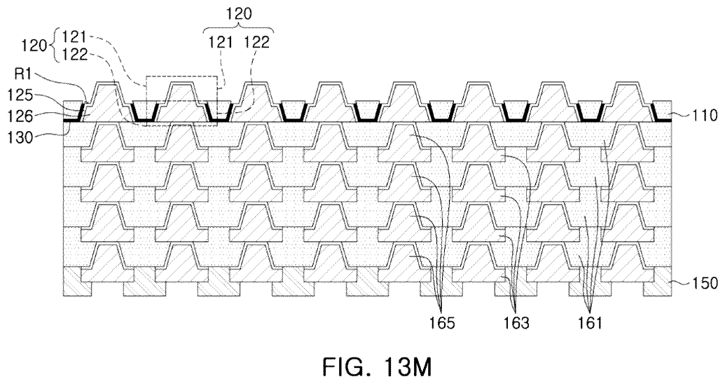

FIGS. 13A to 13M are cross-sectional views schematically illustrating a method of manufacturing a printed circuit board according to the first embodiment.

The method of manufacturing a printed circuit board may include forming a temporary layer (T) on the carrier substrate (C), forming a first insulating layer 110 on the temporary layer (T), forming a first through-hole (h1) penetrating through the first insulating layer 110, forming a second through-hole (h2) penetrating through the temporary layer (T), forming a barrier layer 130 along the inner wall of the first through-hole (h1), the inner wall of the second through-hole (h2), and the lower surface of the first insulating layer 110, forming a first metal layer 120 in the first through-hole (h1) and the second through-hole (h2), and removing the carrier substrate (C) and the temporary layer (T).

In the method of manufacturing a printed circuit board, a first through-hole (h1) is formed to penetrate through the first insulating layer 110, a second through-hole (h2) is formed to penetrate through the temporary layer (T), and the first metal layer 120 is formed after forming the barrier layer 130. Therefore, the first portion 121 of the first metal layer 120 further protrudes than the first insulating layer 110 and the second portion 122 of the first metal layer 120 embedded in the first insulating layer 110 may be formed integrally, and the first metal layer 120 may not be damaged even in the operation of removing the temporary layer (T).

Referring to FIG. 13A, the method of manufacturing a printed circuit board may include forming a temporary layer (T) on a carrier substrate (C). In addition, before forming the temporary layer (T) on the carrier substrate (C), the operation of forming a stopper layer (S) on the carrier substrate (C) may be further included. In this case, the temporary layer (T) may be placed on the stopper layer (S).

The carrier substrate C is used to support the insulating layer and the wiring layer when forming the same, and may be formed of an insulating material or a metal material. In FIG. 13A, the carrier substrate C is illustrated as being composed of one layer, but the present disclosure is not limited thereto, and the carrier substrate C may include a core and copper foil formed on one or both sides of the core. In detail, the carrier substrate (C) is an example of one case, and the carrier substrate (C) may be used by anyone with ordinary knowledge in the relevant technical field, and anything that is used as a support substrate and may be detached or removed later may be used in the present disclosure without any particular restrictions.

The temporary layer (T) may be a layer for forming the first portion 121, which is a protrusion of the first metal layer 120, and may be a temporary structure that is disposed on the carrier substrate (C) and removed after forming the first metal layer 120. The temporary layer (T) may include a metallic material, and the metal material may be copper (Cu), aluminum (Al), silver (Ag), tin (Sn), gold (Au), lead (Pb), titanium (Ti), or alloys thereof. The metal material may in detail include copper (Cu), but is not limited thereto. The temporary layer (T) may be formed by performing electroplating on the carrier substrate (C), in detail, by panel plating, and is not necessarily limited thereto and may be formed by attaching a temporary layer (T). When the temporary layer (T) contains a metal material containing copper (Cu), the temporary layer (T) may be formed in a low-cost manner by forming the temporary layer (T) through plating. Even if the temporary layer (T) contains copper (Cu), the barrier layer 130 is disposed in a step described later, and in the operation of removing the temporary layer (T), the first metal layer 120 may not react and may not be damaged.

On the other hand, the temporary layer T is not limited thereto, and does not contain a metal material, but may include an insulating material. The insulating material may be used without particular restrictions as long as it is an insulating material of the insulating layer that may be used by anyone with ordinary knowledge in the relevant technical field. Since the barrier layer 130 is disposed in the step described later, even if the temporary layer (T) includes an insulating material, the first metal layer 120 may not react and may not be damaged during the operation of removing the temporary layer (T).

On the other hand, before forming the temporary layer (T), forming a stopper layer (S) on the carrier substrate (C) may be further included. The stopper layer (S) may later perform the function of separating the carrier substrate (C) and the temporary layer (T). When forming a second through-hole penetrating through the temporary layer (T), a stopper function may be performed to prevent the carrier substrate (C) from penetrating. The stopper layer (S) may contain a metal material, and the metal material may be nickel (Ni), aluminum (Al), tin (Sn), gold (Au), lead (Pb), titanium (Ti), or alloys thereof. The stopper layer (S) may in detail include nickel (Ni), but is not limited thereto. Afterwards, it must be separated from the temporary layer (T), and since the stopper layer (S) must not be processed at the stage of processing the temporary layer (T), it is sufficient for the stopper layer (S) to be formed of a different metal material from the temporary layer (T), and any material that is easy to separate from the temporary layer (T) may be used without particular restrictions. On the other hand, without being limited thereto, the stopper layer (S) may include various materials such as metal oxides and insulating materials. When processing the temporary layer (T), it is sufficient if the stopper layer (S) has resistance to processing and may perform the function as a stopper.

Referring to FIG. 13B, the method of manufacturing a printed circuit board may include forming a first insulating layer 110 on the temporary layer (T).

The description of the first insulating layer 110 is the same as described above in the printed circuit board, and the method of forming the first insulating layer 110 is a known insulating layer that may be used by those skilled in the art. Any method of forming layers may be used without restrictions.

Referring to FIG. 13C, the method of manufacturing a printed circuit board may include forming a first through-hole (h1) penetrating through the first insulating layer 110.

The first through-hole (h1) may be formed to penetrate the upper and lower surfaces of the first insulating layer 110, and the first through-hole (h1) may include a plurality of through-holes.

Any method of forming the first through-hole h1 may be used without limitation as long as it is processed to penetrate the first insulating layer 110, and as a non-limiting example, may be performed by laser drilling, mechanical drilling, etc., but the present disclosure is not limited thereto, and any method that may penetrate the insulating layer may be used without limitation. On the other hand, when performing laser drilling, a CO₂ laser or YAG laser may be used, but the present disclosure is not limited thereto.

Since the first through-hole (h1) may be processed from the bottom to the top based on FIG. 13C, the first through-hole (h1) may have a shape tapered upwardly. Because the first through-hole (h1) is formed to penetrate the upper and lower surfaces of the first insulating layer 110, the bottom surface located on the opposite side of the open surface of the first through-hole (h1) may be composed of a temporary layer (T). On the other hand, the degree of taper of the first through-hole (h1) may be determined by processing method and conditions.

Referring to FIG. 13D, the method of manufacturing a printed circuit board may include forming a second through-hole (h2) penetrating through the temporary layer (T).

The second through-hole (h2) may be formed to penetrate the upper and lower surfaces of the temporary layer (T), and the second through-hole (h2) may include a plurality of through-holes. The method of forming the second through-hole (h2) may vary depending on the material of the temporary layer (T), and a method of processing the second through-hole (h2) to penetrate the metal layer may be used. Non-limiting examples include, but are not limited thereto, wet etching, dry etching, laser drilling, mechanical drilling, and the like, and may also be formed by combining these processing methods. Any method that may penetrate the temporary layer (T) may be used without restrictions. On the other hand, the present disclosure is not limited thereto, and the second through-hole (h2) formed in the temporary layer (T) may not penetrate the upper and lower surfaces of the temporary layer (T). In this case, the second through-hole (h2) may correspond to a recess from which a portion of the temporary layer (T) has been removed or a hole that penetrates only a portion of the temporary layer (T).

The second through-hole (h2) may be processed starting from the bottom surface of the first through-hole (h1), and may thus be processed from the bottom to the top based on FIG. 13D. The second through-hole (h2) may also have a shape tapered upwardly. When the second through-hole (h2) is formed to penetrate the upper and lower surfaces of the temporary layer (T), the bottom surface located on the opposite side of the open surface of the second through-hole (h2) may be composed of a stopper layer (S). The present disclosure is not necessarily limited thereto, and since the second through-hole (h2) does not completely penetrate the temporary layer (T), the bottom surface of the second through-hole (h2) may be composed of the temporary layer (T). Even though the second through-hole (h2) penetrates the upper and lower surfaces of the temporary layer (T), the stopper layer (S) is formed on the upper side of the temporary layer (T), and the carrier substrate may not be removed.

On the other hand, the degree to which the second through-hole (h2) is tapered may be determined by processing methods and conditions. The second through-hole (h2) corresponds to the area in which the first portion 121, which is a protrusion of the first metal layer 120, will be formed. The shape of the second through-hole (h2) is adjusted to form the first metal layer 120. The shape of the first portion 121 may be designed.

Referring to FIG. 13E, the manufacturing method of the printed circuit board may include forming a barrier layer 130 along the inner wall of the first through-hole (h1), the inner wall of the second through-hole (h2), and the lower surface of the first insulating layer 110.

The barrier layer 130 may be formed using a thin film deposition method, such as an Atomic Layer Deposition (ALD) method or a Molecular Vapor Deposition (MVD) method. As the barrier layer 130 is formed using a thin film deposition method, the barrier layer 130 may include an oxide film that is thinner than the first metal layer. As the barrier layer 130 is formed by a deposition method, the barrier layer 130 may be conformally disposed along the inner wall of the first through-hole (h1), the inner wall of the second through-hole (h2), and the lower surface of the first insulating layer 110. For example, the barrier layer 130 may be formed along the area exposed to the lower side of the intermediate body of the printed circuit board.

Because the barrier layer 130 includes a different material from the temporary layer (T) and the first metal layer 120, after forming the first metal layer 120, the function of protecting the first metal layer 120 may be performed in the operation of removing the temporary layer (T).

Referring to FIG. 13F, a method of manufacturing a printed circuit board may include forming a first metal layer 120. Forming the first metal layer 120 may include forming a seed layer 125 on the barrier layer 130.

The seed layer 125 may be disposed on the barrier layer 130 and along the inner walls of the first through-hole h1 and the second through-hole h2, and the lower surface of the first insulating layer 110. For example, the seed layer 125 may be formed conformally along the barrier layer 130. The seed layer 125 may constitute the outermost layer of the first metal layer 120, and the operation of forming the seed layer 125 may be performed by electroless plating, but is not limited thereto and may also be performed by sputtering. On the other hand, the operation of forming the seed layer 125 is not limited thereto, and any method of forming the seed layer 125 for electroplating may be used without limitation.

Referring to FIG. 13G, a method of manufacturing a printed circuit board may include forming a first metal layer 120. Forming the first metal layer 120 may include forming a plating layer 126 on the seed layer 125.

The plating layer 126 is disposed on the seed layer 125 and may be formed using the seed layer 125 as a plating seed. The plating layer 126 may be formed to fill the first through-hole (h1) and the second through-hole (h2), and may also be formed below the first insulating layer 110. The plating layer 126 may be formed by electroplating, and any method of forming the plating layer 126 that may be used by those skilled in the art may be used without any particular restrictions.

Referring to FIG. 13H, a method of manufacturing a printed circuit board may include forming a first metal layer 120. Forming the first metal layer 120 may include completing the first metal layer 120 by removing a portion of the seed layer 125 and the plating layer 126.

The seed layer 125 functions as a plating lead-in line for the plating layer 126, and is thus formed over the entire lower surface of the first insulating layer 110, and the plating layer 126 is disposed on the seed layer 125 to fill both the first through-hole (h1) and the second through-hole (h2), and may also be formed under the first insulating layer 110. Accordingly, the seed layer 125 and the plating layer 126 may not be electrically connected to each other and may not perform their respective functions. Accordingly, by removing part of the seed layer 125 and the plating layer 126, each first metal layer 120 may be made to perform independent functions. At this time, the operation of removing a portion of the first metal layer 120 may be performed by etching, but is not limited thereto.

On the other hand, referring to FIGS. 13F to 13H, it is illustrated that the first metal layer 120 is formed by forming the seed layer 125 by electroless plating and then forming the plating layer 126 by electroplating, but the present disclosure is not necessarily limited thereto. The method of forming the first metal layer 120 may be performed by filling the first through-hole h1 and the second through-hole h2 with a paste containing a metal material and then firing the same. The method of forming the first metal layer 120 may not be limited thereto, and it is sufficient if the first metal layer 120 may be formed on the barrier layer 130 and fill the first through-hole (h1) and the second through-hole (h2), and any method of forming a metal layer that may be used by those skilled in the art may be used without any particular restrictions.

Referring to FIG. 13I, the manufacturing method of the printed circuit board may include forming a second insulating layer 161 on the lower surface of the first insulating layer 110, forming a first wiring layer 163 on the second insulating layer 161, and forming a first via layer 165 penetrating at least a portion of the second insulating layer 161 to connect the first metal layer 120 and the first wiring layer 163 to each other. Additionally, the operation of forming a solder resist layer 150 on the second insulating layer 161 may be further included.

As the method of forming the second insulating layer 161, the method of forming the first wiring layer 163 and the first via layer 165, and the method of forming the solder resist layer 150, any build-up method of the insulating layer and wiring layer that may be used by anyone with ordinary knowledge in the relevant technical field may be used without limitation.

Referring to FIG. 13J, the method of manufacturing a printed circuit board may include removing the carrier substrate (C). The operation of removing the carrier substrate (C) may be performed using various methods depending on the shape of the carrier substrate (C). For example, in the operation of removing the carrier substrate (C), the copper foil may be removed sequentially after removing the core included in the carrier substrate, or the carrier substrate may be removed as one piece, for example, the core and the copper foil may be removed simultaneously. The operation of removing the carrier substrate (C) may be performed using a known process used for carrier detach without limitation.

Referring to FIG. 13K, the method of manufacturing a printed circuit board may include removing the stopper layer (S). The operation of removing the stopper layer (S) may be performed by etching, but is not limited thereto. The operation of removing the stopper layer (S) may be performed in different processes depending on the constituent material of the stopper layer (S), and any process that may remove the constituent materials of the stopper layer (S) may be used without limitation. For example, different conditions may be implemented depending on the material of the stopper layer (S). Because the stopper layer (S) and the temporary layer (T) may contain different materials, such as the stopper layer (S) containing a different metal from the temporary layer (T), in the operation of removing the stopper layer (S), the temporary layer (T) may not be removed. As the stopper layer (S) is removed, the upper side of the barrier layer 130 may be exposed to the outside. Since the barrier layer 130 may not react to the etching of the stopper layer (S), the barrier layer 130 and the first metal layer 120 may not react in the operation of removing the stopper layer (S).

Referring to FIG. 13L, the method of manufacturing a printed circuit board may include removing the temporary layer (T). The operation of removing the temporary layer (T) may be performed by etching, but is not limited thereto. The operation of removing the temporary layer (T) may be performed through different processes depending on the constituent material of the temporary layer (T), and any process that may remove the constituent materials of the temporary layer (T) may be used without limitation. In detail, different conditions may be implemented depending on the material of the temporary layer (T).

Since the barrier layer 130 is formed between the temporary layer (T) and the first metal layer 120, the first metal layer 120 may not react in the operation of removing the temporary layer (T) and may be protected. In detail, even if etching is performed to remove the temporary layer (T) in a state where the first metal layer 120 and the temporary layer (T) contain the same metal material, since the first metal layer 120 is covered by the barrier layer 130, only the temporary layer T may be removed, and the first metal layer 120 may not react. For example, since the barrier layer 130 covering the first metal layer 120 is formed, the temporary layer (T) may be selected as a material that may be formed and removed at a low cost, and therefore, a low-cost printed circuit board manufacturing method may be implemented.

Through the operation of removing the temporary layer T, the first portion 121, which is a protrusion of the first metal layer 120, may protrude beyond the first insulating layer 110. For example, the first portion 121 of the first metal layer 120 protrudes beyond the first insulating layer 110 and may function as a metal post. Since the first metal layer 120 may be protected by the barrier layer 130, reliability may be secured when combined with electronic components.

Referring to FIG. 13M, a method of manufacturing a printed circuit board may include removing a portion of the barrier layer 130. The operation of removing a portion of the barrier layer 130 may be performed by etching, and dry etching or wet etching may be used, but is not necessarily limited thereto. In the operation of removing a portion of the barrier layer 130, only a portion of the barrier layer 130 disposed in a protruding area of the first metal layer 120 may be removed. For example, the barrier layer 130 disposed on the first portion 121 of the first metal layer 120 may be removed, and the barrier layer 130 disposed on the upper surface of the second portion 122 may be removed. At this time, as the barrier layer 130 disposed on the upper surface of the second portion 122 is removed, the upper surface of the second portion 122 of the first metal layer 120 may have a step difference from the upper surface of the first insulating layer 110. For example, a portion of the barrier layer 130 may be removed, and a first recess R1 having a step equal to the thickness of the barrier layer 130 may be formed in the first metal layer 120. As a portion of the barrier layer 130 is removed, a portion of the first metal layer 120 may be exposed to the outside, and the outside of the first metal layer 120 may be connected to other components such as electronic components. In detail, since the first portion 121, which is a protrusion of the first metal layer 120, is exposed to the outside, the protrusion may be connected to electronic components, etc. as a metal post.

FIGS. 13A to 13M illustrate that components are formed only on the lower side of the carrier substrate (C) based on each drawing. However, the same process may be performed on the upper surface of the carrier substrate (C) to manufacture a printed circuit board with a symmetrical structure. In this case, two printed circuit boards with the same structure may be manufactured using one carrier board (C). In addition, without being limited thereto, after a plurality of substrates are implemented in the form of a strip board on one carrier substrate (C), each printed circuit board may be cut to manufacture a plurality of printed circuit boards.

In addition, the general configuration of the printed circuit board may be further included, as described above in the description of the printed circuit board, and may be freely added or omitted if it does not change the technical meaning of the present disclosure.

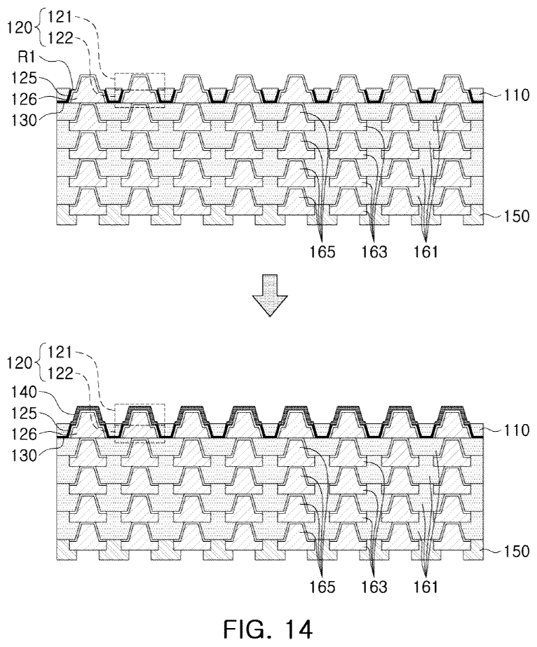

FIG. 14 is a cross-sectional view schematically illustrating an operation of the method of manufacturing a printed circuit board according to the second embodiment.

Referring to FIG. 14, the method of manufacturing a printed circuit board according to the second embodiment may further include forming a surface treatment layer 140 on the first metal layer 120. The surface treatment layer 140 may be formed in an externally exposed area of the first metal layer 120, be formed on the first portion 121 of the first metal layer 120 and be formed on the upper surface of the second portion 122. The surface treatment layer 140 may be formed through electroless plating and substitution plating, but is not necessarily limited thereto, and different manufacturing methods may be applied depending on the structure of the surface treatment layer 140. Additionally, if the surface treatment layer has an organic film structure containing an organic material, the surface treatment layer may be formed through organic film coating. In this manner, any method of forming the surface treatment layer 140 that may be used by anyone with ordinary knowledge in the relevant technical field may be used without any particular restrictions.

On the other hand, FIG. 14 illustrates operations after FIG. 13M of the method of manufacturing a printed circuit board according to the first embodiment, and among operations other than forming the surface treatment layer 140, the same configuration as the method of manufacturing a printed circuit board according to the first embodiment may be applied to the method of manufacturing a printed circuit board according to the second embodiment, and redundant descriptions related thereto will be omitted.

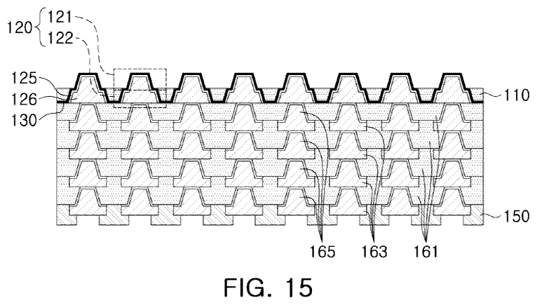

FIG. 15 is a cross-sectional view schematically illustrating an operation of the method of manufacturing a printed circuit board according to the third embodiment.

Referring to FIG. 15, the method of manufacturing a printed circuit board according to the third embodiment may not include removing a portion of the barrier layer 130. For example, the printed circuit board according to the third embodiment may be completed at the operation of removing the carrier substrate (C) and the temporary layer (T). Therefore, in the printed circuit board according to the third embodiment, the barrier layer 130 may be disposed on the outermost surface of the first metal layer 120.

On the other hand, FIG. 15 illustrates operations after FIG. 13L of the method of manufacturing a printed circuit board according to the first embodiment, and among the operations other than removing part of the barrier layer 130, the same configuration as the method of manufacturing a printed circuit board according to the first embodiment may be applied to the method of manufacturing a printed circuit board according to the third embodiment, and thus redundant descriptions are omitted.

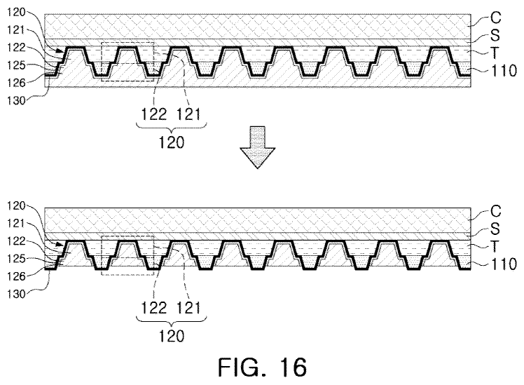

FIG. 16 is a cross-sectional view schematically illustrating an operation of the method of manufacturing a printed circuit board according to the fourth embodiment.

Referring to FIG. 16, the method of manufacturing a printed circuit board according to the fourth embodiment may have a structure in which the lower surface of the first metal layer 120 is recessed than the lower surface of the first insulating layer 110, in the operation of forming the first metal layer 120. In detail, in the operation of completing the first metal layer 120 by removing a portion of the seed layer 125 and the plating layer 126, a second recess R2 may be formed in the first metal layer 120. The second recess R2 may be formed when a portion of the seed layer 125 and the plating layer 126 are removed by an etching solution, which may be the result of overetching during wet etching. The second recess R2 may be filled with the second insulating layer 161 in a later operation. Because the second insulating layer 161 is filled in the second recess R2, the contact area between the second insulating layer 161 and the barrier layer 130 increases, so that the adhesion of the second insulating layer 161 may be further secured.

On the other hand, FIG. 16 illustrates only a portion of the operations after FIG. 13G of the method of manufacturing a printed circuit board according to the first embodiment, and among the operations other than forming the first metal layer 120, the same configuration as the method of manufacturing the printed circuit board according to the first embodiment may also be applied to the method of manufacturing a printed circuit board according to the fourth embodiment, and thus redundant descriptions related thereto will be omitted.

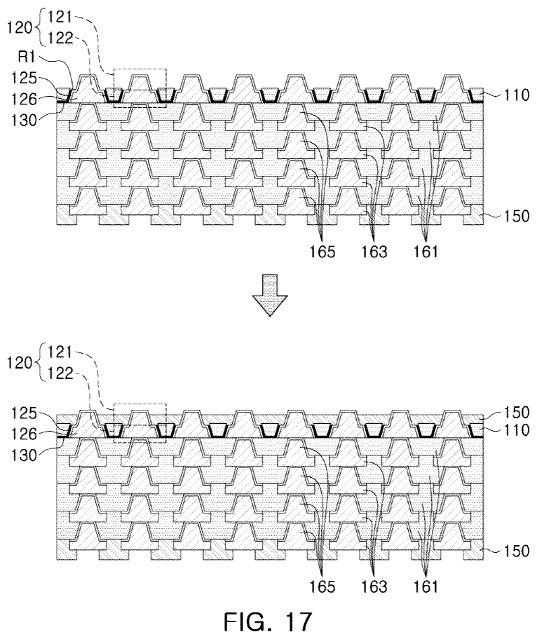

FIG. 17 is a cross-sectional view schematically illustrating an operation of the method of manufacturing a printed circuit board according to the fifth embodiment.

Referring to FIG. 17, the method of manufacturing a printed circuit board according to the fifth embodiment may further include forming a solder resist layer 150 on the first insulating layer 110. In detail, after removing a portion of the barrier layer 130, forming a solder resist layer 150 on the first insulating layer 110 may be further included.

Because in the operation of removing a portion of the barrier layer 130, a portion of the barrier layer 130 disposed in the area protruding above the first insulating layer 110 is removed, and the solder resist layer 150 may be formed to contact a portion of the first metal layer 120. At this time, the thickness of the solder resist layer 150 may be designed so that the first metal layer 120 protrudes beyond the solder resist layer 150. However, the present disclosure is not limited thereto, and the first metal layer 120 may be exposed by removing a portion of the solder resist layer 150 after forming the same. In this case, there may be a method of forming an opening in the solder resist layer 150, or a method of removing a portion of the solder resist layer 150 to make the layer thickness thinner. The solder resist layer 150 may be formed by applying a liquid-type solder resist or a film-type solder resist and then curing it, but is not limited thereto. Anyone with ordinary knowledge in the relevant technical field may use any known method of forming a solder resist without limitation.

On the other hand, FIG. 17 illustrates operations after FIG. 13M of the method of manufacturing a printed circuit board according to the first embodiment, and among the operations other than forming the solder resist layer 150, the same configuration as the method of manufacturing the printed circuit board according to the first embodiment may also be applied to the method of manufacturing a printed circuit board according to the fifth embodiment, and thus redundant descriptions related thereto will be omitted.

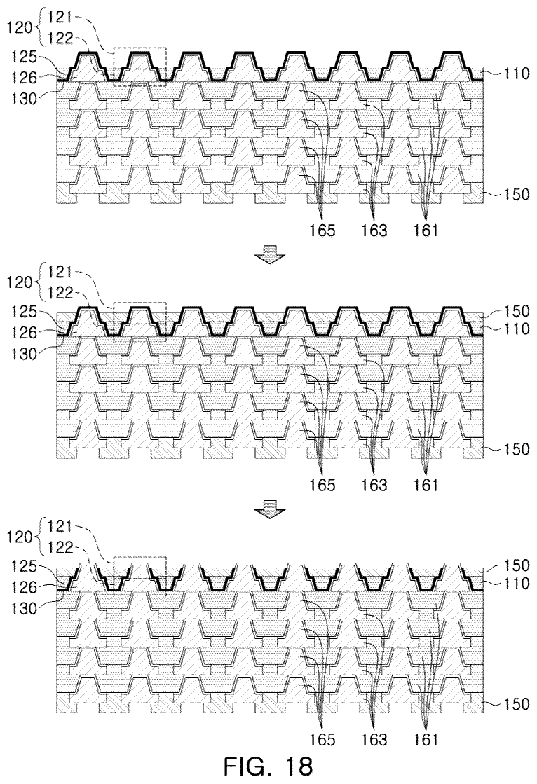

FIG. 18 is a cross-sectional view schematically illustrating an operation of the method of manufacturing a printed circuit board according to the sixth embodiment.

Referring to FIG. 18, the method of manufacturing a printed circuit board according to the sixth embodiment may further include forming a solder resist layer 150 on the first insulating layer 110. In detail, before removing a portion of the barrier layer 130, forming a solder resist layer 150 on the first insulating layer 110 may be further included, and after forming the solder resist layer 150, an operation of removing a portion of the barrier layer 130 may be included.

Since the solder resist layer 150 is formed on the first insulating layer 110 before removing a portion of the barrier layer 130, the solder resist layer 150 may be in contact with the barrier layer 130. At this time, the thickness of the solder resist layer 150 may be designed so that the first metal layer 120 protrudes beyond the solder resist layer 150. However, the present disclosure is not limited thereto, and the first metal layer 120 may be exposed by removing a portion of the solder resist layer 150 after forming the same. In this case, there may be a method of forming an opening in the solder resist layer 150, or a method of removing a portion of the solder resist layer 150 to make the layer thickness thinner.

The solder resist layer 150 may be formed by applying a liquid-type solder resist or a film-type solder resist and then curing the same. The present disclosure is not limited thereto, and any method for forming a known solder resist that may be used by those with ordinary knowledge in the relevant technical field may be used without limitation.

After forming the solder resist layer 150, an operation of removing a portion of the barrier layer 130 is performed, and a portion of the barrier layer 130 disposed in the area protruding above the solder resist layer 150 may be removed, and a portion of the first metal layer 120 may be exposed to the outside. At this time, in the step where part of the barrier layer 130 is removed, the solder resist layer 150 may not react.

On the other hand, FIG. 18 illustrates operations after FIG. 13L of the method of manufacturing a printed circuit board according to the first embodiment, and among operations other than forming the solder resist layer 150 and removing part of the barrier layer 130, the same configuration as the method of manufacturing a printed circuit board according to another embodiment may also be applied to the method of manufacturing a printed circuit board according to the sixth embodiment, and thus redundant description thereof will be omitted.

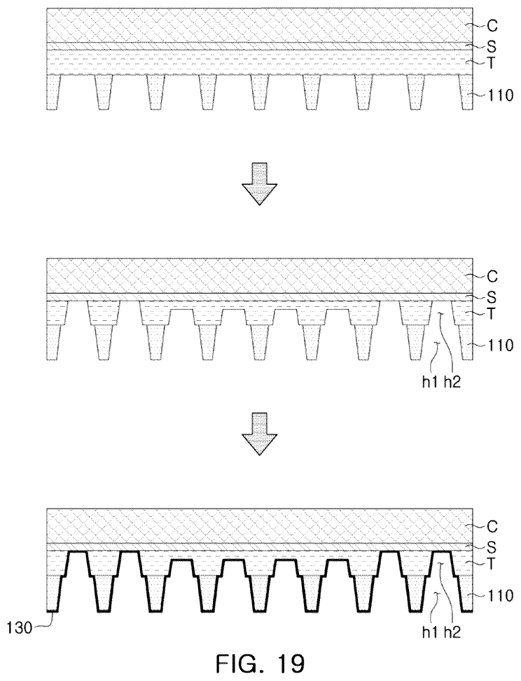

FIG. 19 is a cross-sectional view schematically illustrating an operation of the method of manufacturing a printed circuit board according to the seventh embodiment.

Referring to FIG. 19, the operation of forming the second through-hole (h2) in the method of manufacturing a printed circuit board according to the seventh embodiment may be performed by forming a plurality of second through-holes (h2) with different depths. For example, the second through-hole (h2) penetrating through the temporary layer (T) may include a plurality of second through-holes (h2) with different depths. At this time, at least some of the second through-holes (h2) may not penetrate the upper and lower surfaces of the temporary layer (T). For example, the second through-hole (h2) may correspond to a recess from which a portion of the temporary layer (T) has been removed or a hole that penetrates only a portion of the temporary layer (T).

This may be the result of performing processing to change the conditions of the temporary layer (T) in the operation of forming the second through-hole (h2). At this time, processing with different processing conditions may be performed multiple times, but the process is not necessarily limited thereto, and a second through-hole (h2) with a different depth may be formed through one processing. At this time, the deep second through-hole h2 may be formed to surround the shallow second through-hole h2, but is not necessarily limited thereto. The second through-hole (h2) with a different depth may later appear as a difference in height between the first portion 121 of the first metal layer 120 and as a difference in thickness of the metal post.

After forming the second through-hole h2, forming the barrier layer 130 may be performed. The barrier layer 130 may be conformally disposed along the inside of the plurality of second through-holes (h2).

On the other hand, FIG. 19 illustrates only a portion of the steps after FIG. 13C of the method of manufacturing a printed circuit board according to the first embodiment, and among the operations other than forming the second through-hole h2, the same configuration as the method of manufacturing a printed circuit board according to another embodiment may be applied to the method of manufacturing a printed circuit board according to the seventh embodiment, and thus redundant descriptions related thereto will be omitted.

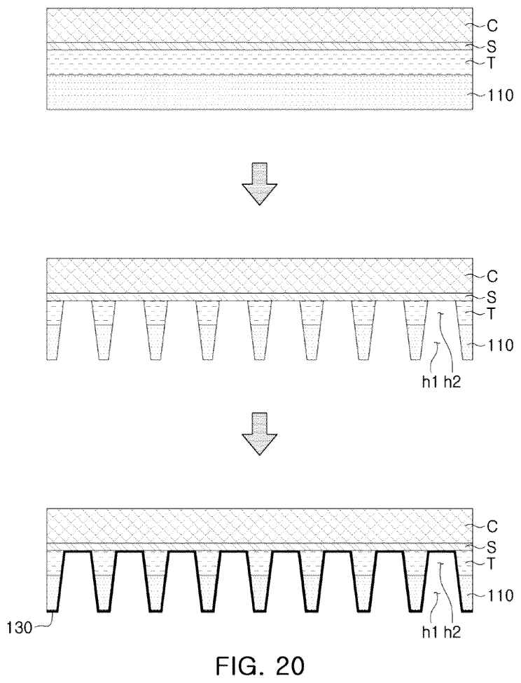

FIG. 20 is a cross-sectional view schematically illustrating an operation of the method of manufacturing a printed circuit board according to the eighth embodiment.

Referring to FIG. 20, the operations of forming the first through-hole (h1) and the operation of forming the second through-hole (h2) in the method of manufacturing a printed circuit board according to the eighth embodiment may be performed simultaneously. For example, the operation of forming the first through-hole (h1) penetrating through the first insulating layer 110 and the operation of forming the second through-hole (h2) penetrating through the temporary layer (T) may be performed simultaneously. As the first through-hole (h1) and the second through-hole (h2) are formed simultaneously, the upper surface of the first through-hole (h1) located on the upper surface of the first insulating layer 110 and the lower surface of the second through-hole (h2) located on the lower surface of the temporary layer (T) may have substantially the same width. On the other hand, in FIG. 20, the inner wall of the first through-hole h1 and the inner wall of the second through-hole h2 are illustrated as having a substantially constant inclination to each other, but this is not necessarily limited. The slope of the inner wall of the first through-hole (h1) and the slope of the inner wall of the second through-hole (h2) may be different from each other. On the other hand, the second through-hole (h2) formed in the temporary layer (T) may not penetrate the upper and lower surfaces of the temporary layer (T). In this case, the second through-hole (h2) may correspond to a recess from which a portion of the temporary layer (T) has been removed or a hole that penetrates only a portion of the temporary layer (T).

On the other hand, FIG. 20 illustrates only a portion of the steps after FIG. 13B of the method of manufacturing a printed circuit board according to the first embodiment, and among operations other than forming the first through-hole (h1) and the second through-hole (h2), the same configuration as the method of manufacturing a printed circuit board according to another embodiment may also be applied to the method of manufacturing a printed circuit board according to the eighth embodiment, and thus redundant description thereof will be omitted.

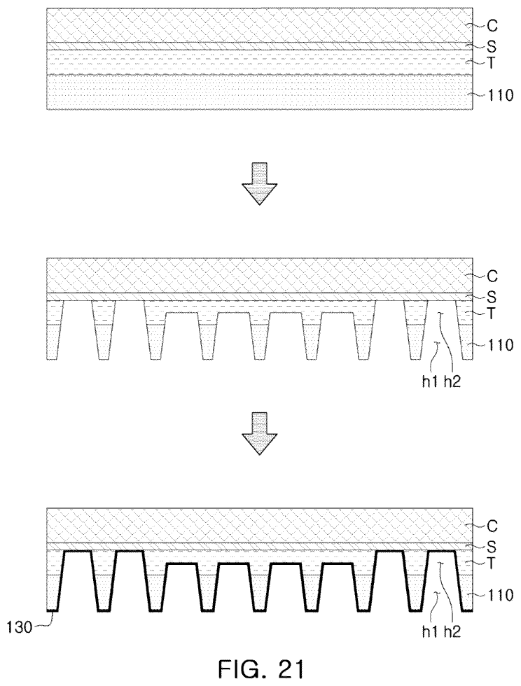

FIG. 21 is a cross-sectional view schematically illustrating an operation of the method of manufacturing a printed circuit board according to the ninth embodiment.

Referring to FIG. 21, the operations of forming the first through-hole (h1) and the operation of forming the second through-hole (h2) of the method of manufacturing a printed circuit board according to the ninth embodiment may be performed simultaneously, and the second through-hole (h2) may include a plurality of second through-holes (h2) having different depths. This is the result of simultaneously forming the first through-hole (h1) penetrating through the first insulating layer 110 and forming the second through-hole h2 penetrating through the temporary layer (T). This may be the result of designing the hole formation conditions differently. The shape of the first metal layer 120 of the printed circuit board may be adjusted by adjusting the shape of the first through-hole (h1) and the second through-hole (h2). At this time, at least a portion of the second through-hole (h2) may not penetrate the upper and lower surfaces of the temporary layer (T). For example, at least a portion of the second through-hole (h2) may correspond to a recess from which a portion of the temporary layer (T) has been removed or a hole that penetrates only a portion of the temporary layer (T).

On the other hand, FIG. 21 illustrates only a portion of the steps after FIG. 13B of the method of manufacturing a printed circuit board according to the first embodiment, and among operations other than forming the first through-hole (h1) and the second through-hole (h2), since the same configuration as the printed circuit board manufacturing method according to the other embodiments may also be applied to the printed circuit board manufacturing method according to the ninth embodiment, redundant descriptions related thereto will be omitted.

As set forth above, according to embodiments, a printed circuit board, in which connection with electronic components having high-density microcircuits and/or connection with a main board may be performed, and a method of manufacturing the printed circuit board, may be provided.

A printed circuit board in which a microcircuit-implemented structure protrudes to an outermost surface, and a method of manufacturing the printed circuit board, may be provided.

A printed circuit board having improved reliability and a method of manufacturing the printed circuit board may be provided.

In the present disclosure, the meaning of cross-section may mean the cross-sectional shape when the object is cut vertically, or the cross-sectional shape when the object is viewed from a side view. Additionally, the meaning on a plane may be the shape when the object is cut horizontally, or the plane shape when the object is viewed from a top-view or bottom-view.

In the present disclosure, upper side, upper side, upper surface, etc. are used for convenience to refer to the direction toward the surface on which electronic components may be mounted based on the cross section of the drawing, and lower side, bottom, lower surface, etc. are used in the opposite direction. However, this direction is defined for convenience of explanation, and of course, the scope of the patent claims is not particularly limited by the description of this direction.

In the present disclosure, the meaning of connected is a concept that includes not only directly connected, but also indirectly connected through an adhesive layer or the like. In addition, the meaning of being electrically connected is a concept that includes both cases where it is physically connected and cases where it is not connected. Additionally, expressions such as first, second, etc. are used to distinguish one component from another component and do not limit the order and/or importance of the components. In some cases, the first component may be named the second component without departing from the scope of rights, and similarly, the second component may be named as the first component.

In the present disclosure, the judgment may actually include process errors, position deviations, errors during measurement, etc. that occur during the manufacturing process. For example, substantially vertical may include not only completely vertical, but also approximately vertical. In addition, substantially coplanar may include not only the case of being completely on the same plane, but also the case of being approximately on the same plane. In addition, substantially tapering may include not only a case in which the width changes with a completely constant inclination, but also a case in which the width on one side and the opposite side are roughly changed to be different.

In the present disclosure, the same material may mean not only the exact same material but also including the same type of material. Accordingly, the composition of the materials is substantially the same, but their specific composition ratios may be slightly different.

The expression ‘example’ used in the present disclosure does not mean identical embodiments, but is provided to emphasize and explain different unique features. However, the examples presented above do not exclude being implemented in combination with features of other examples. For example, even if what is described in an example is not described in another example, unless there is a contrary or contradictory explanation in another example, it may be understood as an explanation related to another example.

The terminology used in this disclosure is used to describe examples only and is not intended to limit the disclosure. At this time, singular expressions include plural expressions, unless the context clearly indicates otherwise.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a first insulating layer;
a first metal layer having a first portion protruding upwardly of the first insulating layer and a second portion embedded in the first insulating layer; and
a barrier layer disposed between the first insulating layer and the second portion and extending to a lower surface of the first insulating layer,
wherein the first portion and the second portion are integrated.

2. The printed circuit board of claim 1, wherein a width of a lower surface of the first portion is narrower than a width of an upper surface of the second portion.

3. The printed circuit board of claim 1, wherein the first portion and the second portion respectively have a tapered shape, and
a tapered direction of the first portion and a tapered direction of the second portion are substantially the same.

4. The printed circuit board of claim 3, wherein the second portion has the tapered shape having a width becoming narrower toward a top.

5. The printed circuit board of claim 1, wherein at least a portion of an upper surface of the second portion is not covered by the first insulating layer.

6. The printed circuit board of claim 1, wherein the first metal layer includes a first recess, such that an upper surface of the second portion and an upper surface of the first insulating layer have a step.

7. The printed circuit board of claim 6, wherein a depth of the first recess is substantially equal to a thickness of the barrier layer.

8. The printed circuit board of claim 1, wherein the first metal layer includes a seed layer and a plating layer disposed on the seed layer,
wherein the seed layer is disposed outside the first metal layer.

9. The printed circuit board of claim 8, wherein the seed layer is provided integrally along an outer side of the first portion and an outer side of the second portion.

10. The printed circuit board of claim 9, wherein the plating layer is integrally provided with the first portion and the second portion.

11. The printed circuit board of claim 1, further comprising a surface treatment layer disposed on the first metal layer.

12. The printed circuit board of claim 11, wherein a thickness of the surface treatment layer is greater than a thickness of the barrier layer.

13. The printed circuit board of claim 12, wherein the first metal layer includes a first recess such that an upper surface of the second portion and an upper surface of the first insulating layer have a step, and
the surface treatment layer is disposed at least in the first recess.

14. The printed circuit board of claim 1, wherein a lower surface of the first metal layer and a lower surface of the barrier layer are substantially coplanar.

15. The printed circuit board of claim 14, wherein the lower surface of the first metal layer protrudes further than an extended surface of the lower surface of the first insulating layer.

16. The printed circuit board of claim 1, wherein a lower surface of the first metal layer and a lower surface of the barrier layer have a step.

17. The printed circuit board of claim 16, wherein the lower surface of the first metal layer has a structure further recessed than an extended surface of the lower surface of the first insulating layer.

18. The printed circuit board of claim 1, further comprising a solder resist layer disposed on the first insulating layer,
wherein the first metal layer penetrates through the solder resist layer and at least a portion of the first portion protrudes from the solder resist layer.

19. The printed circuit board of claim 18, wherein the barrier layer extends between the first metal layer and the solder resist layer.

20. The printed circuit board of claim 1, further comprising:
a first connecting member disposed on the first metal layer; and
a first electronic component disposed on the first connecting member and connected to the first metal layer.

21. The printed circuit board of claim 1, wherein the first metal layer includes a first metal post and a second metal post,
wherein a thickness of the first metal post is greater than a thickness of the second metal post.

22. The printed circuit board of claim 1, wherein a width of a lower surface of the first portion and a width of an upper surface of the second portion are substantially the same.

23. The printed circuit board of claim 22, wherein the first metal layer has a tapered shape with a width becoming narrower toward a top.

24. The printed circuit board of claim 22, wherein the first metal layer includes a first metal post and a second metal post,
wherein a thickness of the first metal post is greater than a thickness of the second metal post.

25. The printed circuit board of claim 1, wherein the barrier layer extends to cover at least a portion of the first portion.

26. The printed circuit board of claim 25, wherein the barrier layer covers an upper surface of the second portion.

27. The printed circuit board of claim 26, wherein the barrier layer covers substantially an entirety of the second portion.

28. The printed circuit board of claim 25, further comprising a first connecting member disposed on a portion of the first portion,
wherein the barrier layer is not disposed on a portion of the first portion in contact with the first connecting member.

29. The printed circuit board of claim 28, wherein the first connecting member covers at least a portion of an upper surface and at least a portion of a side surface of the first portion.

30. The printed circuit board of claim 28, wherein the first connecting member includes a first metal, and
the barrier layer includes an oxide of the first metal.

31. The printed circuit board of claim 30, wherein the first metal includes aluminum (Al).

32. The printed circuit board of claim 1, wherein the barrier layer does not cover an upper surface of the first insulating layer.

33. The printed circuit board of claim 1, wherein the barrier layer includes at least one material selected from Al₂O₃, SiO₂, TiO₂, ZnO, ZrO₂, HfO₂, or La₂O₃.

34. The printed circuit board of claim 1, further comprising:
a second insulating layer disposed below the first insulating layer;
a first wiring layer disposed on the second insulating layer; and
a first via layer penetrating through at least a portion of the second insulating layer to connect the first wiring layer and the first metal layer.

35. A method of manufacturing a printed circuit board, comprising:
forming a temporary layer on a carrier substrate;
forming a first insulating layer on the temporary layer;
forming a first through-hole penetrating through the first insulating layer;
forming a recess by removing at least a portion of the temporary layer;
forming a barrier layer along an inner wall of the first through-hole, an inner wall of the recess, and a lower surface of the first insulating layer;
forming a first metal layer in the first through-hole and the recess; and
removing the carrier substrate and the temporary layer.

36. The method of claim 35, further comprising removing a portion of the barrier layer after the removing the temporary layer.

37. The method of claim 35, wherein the forming the recess includes forming a second through-hole penetrating through the temporary layer.

38. The method of claim 35, wherein the forming the temporary layer is performed by plating.

39. The method of claim 35, further comprising forming a stopper layer on the carrier substrate before the forming the temporary layer,
wherein the temporary layer includes a metallic material, and
wherein the stopper layer includes a metal material substantially different from the temporary layer.

40. The method of claim 35, wherein the forming the barrier layer is performed by a deposition process.

41. The method of claim 35, wherein the forming the first through-hole and the forming the recess are performed simultaneously.

42. The printed circuit board of claim 34, wherein the barrier layer is spaced apart from the first via layer.

43. The printed circuit board of claim 34, wherein with respect to an interface between the first metal layer and the second insulating layer, a height of the first insulating layer is greater than a height of the barrier layer.

44. The printed circuit board of claim 1, wherein side surfaces of the first portion and the second portion have a step therebetween.
